(19) United States
(12) Patent Application Publication
(10) Pub. No.: US 2013/0087757 A1
(43) Pub. Date: Apr. 11, 2013

(54) RESISTIVE MEMORY DEVICE AND METHOD OF MANUFACTURING THE SAME

(71) Applicants: Wei-Su Chen, Hsinchu City (TW); Frederick T. Chen, Hsinchu County (TW); Shan-Yi Yang, Hsinchu City (TW); Peng-Sheng Chen, Tainan City (TW)

(72) Inventors: Wei-Su Chen, Hsinchu City (TW); Frederick T. Chen, Hsinchu County (TW); Shan-Yi Yang, Hsinchu City (TW); Peng-Sheng Chen, Tainan City (TW)

(73) Assignee: INDUSTRIAL TECHNOLOGY RESEARCH INSTITUTE, Hsinchu (TW)

(21) Appl. No.: 13/339,342

(22) Filed: Dec. 28, 2011

(30) Foreign Application Priority Data
Oct. 5, 2011 (TW) 100136379

(51) Int. Cl. H01L 45/00; H01L 21/62

(52) U.S. Cl. 257/4; 438/382; 257/E21.52; 257/E45.002

(57) ABSTRACT

A method of manufacturing a resistive memory device is provided. A bottom electrode and a cup-shaped electrode connected to the bottom electrode are formed in an insulating layer. A cover layer extends along a first direction is formed and covers a first area surrounded by the cup-shaped electrode and exposes a second area and a third area surrounded by the cup-shaped electrode. A sacrificial layer is formed above the insulating layer. A stacked layer extends along a second direction and covers the second area surrounded by the cup-shaped electrode and a portion of the corresponding cover layer is formed. A conductive spacer material layer is formed on the stacked layer and the sacrificial layer. By using the sacrificial layer as an etch stop layer, the conductive spacer material layer is etched to form a conductive spacer at the sidewall of the stacked layer.

### CROSS-REFERENCE TO RELATED APPLICATION

This application claims the priority benefit of Taiwan application serial no. 100136379, filed on Oct. 5, 2011. The entirety of the above-mentioned patent application is hereby incorporated by reference herein and made a part of this specification.

### BACKGROUND

1. Technical Field

The disclosure relates to a semiconductor memory device and a method of manufacturing the same. More particularly, the disclosure relates to a resistive memory device and a method of manufacturing the same.

2. Related Art

Nonvolatile memory is capable of saving stored data after the power is turned off and is thus an indispensable memory device for many electronic products to function properly. Currently, resistive random access memory (RRAM) is a type of nonvolatile memory that is being actively developed in the industry. RRAM has low write-in operation voltage, short write in erase time, long memorizing time, non-destructive read out, multi-state memory, simple structure, and small required area. Consequently, RRAM has great potential in the applications in personal computers and electronic apparatuses in the future.

In RRAM, the state of a film adopted as a resistance variable layer is changed by using a current pulse and applying a conversion voltage so as to conduct a conversion between a set state and a reset state based on different resistances under different states. The digital data of 0 and 1 is saved in the memory by utilizing the different resistances between set states and reset states thereof.

However, the complexity and the cost in fabrication increases significantly as the size of the resistive memory device becomes smaller. Accordingly, the industry has been focusing on reducing the size of the resistive memory device to increase the integration of the resistive memory device and reduce the cost.

### SUMMARY

A method of manufacturing a resistive memory device is provided. The manufacturing method is capable of manufacturing ultra-small active regions with a simple fabrication to confine a plurality of locations which variable resistances are formed at in the resistive memory device. As a consequence, a set state and a reset state of the variable resistances are more stable and resistance distributions thereof are more tight.

A resistive memory device having a plurality of ultra-small active regions beyond the limits of a photolithography machine is introduced herein.

A method of manufacturing a resistive memory device is provided herein. In this method, a bottom electrode and a cup-shaped electrode are formed in an insulating layer. The cup-shaped electrode has a bottom portion connected to the bottom electrode. A cover layer is formed to cover a first area surrounded by the cup-shaped electrode and expose a second area and a third area surrounded by the cup-shaped electrode. A sacrificial layer, a dielectric layer, and a top electrode layer are formed. The dielectric layer and the top electrode layer are patterned using the sacrificial layer as an etch stop layer to form a stacked structure. The stacked structure covers a top of the second area, a top of a portion of the first area surrounded by the cup-shaped electrode, and the sacrificial layer above the insulating layer. A conductive spacer material layer is formed on the insulating layer and the sacrificial layer. The conductive spacer material layer is etched using the sacrificial layer as the etch stop layer to form a conductive spacer at a sidewall of the stacked structure. A portion of the sacrificial layer is removed using the conductive spacer and the stacked structure as a mask to expose a surface of a portion of the cover layer, the third area surrounded by the cup-shaped electrode, and the insulating layer at the periphery of the portion of the cover layer and the third area.

A resistive memory device including a bottom electrode, a cup-shaped electrode, a cover layer, a stacked structure, a sacrificial layer, a conductive spacer, and a resistance variable layer is introduced herein. The bottom electrode and the cup-shaped electrode are located in the insulating layer. The cup-shaped electrode is located above the bottom electrode and has a bottom portion connected to the bottom electrode. The cover layer covers a first area surrounded by the cup-shaped electrode and exposes a second area and a third area surrounded by the cup-shaped electrode. The stacked structure includes a dielectric layer and a top electrode. The stacked structure extends along a second direction, covers a portion of the cover layer on the first area and the second area surrounded by the cup-shaped electrode, and exposes another portion of the cover layer on the first area and the third area surrounded by the cup-shaped electrode. The sacrificial layer is located below the stacked structure and covers a corresponding portion of the cover layer and the second area surrounded by the cup-shaped electrode. The conductive spacer is located at a sidewall of the stacked structure.

A resistive memory device including a substrate, a first resistive memory device and a second resistive memory device is introduced herein. The first resistive memory device is located on the substrate. The second resistive memory device is located on the first resistive memory device and electrically connected to the first resistive memory device. The first resistive memory device and the second resistive memory device each includes a bottom electrode, a diode, a cup-shaped electrode, a cover layer, a stacked structure, a sacrificial layer, a conductive spacer, and a resistance variable layer. The diode is located in a first insulating layer above the bottom electrode. The cup-shaped electrode is located in the first insulating layer. The cup-shaped electrode contacts and is electrically connected to the diode. The cover layer covers a first area surrounded by the cup-shaped electrode and exposes a second area and a third area surrounded by the cup-shaped electrode. The stacked structure includes a dielectric layer and a top electrode. The stacked structure covers a portion of the cover layer on the first area and the second area surrounded by the cup-shaped electrode, and exposes another portion of the cover layer on the first area and the third area surrounded by the cup-shaped electrode. The sacrificial layer is located below the stacked structure and covers a corresponding portion of the cover layer and the second area surrounded by the cup-shaped electrode. The conductive spacer is located at a sidewall of the stacked structure.

A method of manufacturing a resistive memory device in the exemplary embodiment is introduced herein. The manufacturing method is capable of manufacturing ultra-small active regions beyond the limits of a photolithography machine with a simple fabrication to confine a plurality of locations which variable resistances are formed at in the resistive memory device. As a consequence, a set state and a reset state of the variable resistances are more stable and resistance distributions thereof are more tight.

In the method of manufacturing the resistive memory device in the exemplary embodiment, the resistance variable layer is no longer damaged by possible charge accumulation from any plasma etching processes. As a result, the insulating quality is higher and the set state and the reset state of the variable resistances are more stable and the resistance distributions are more tight, such that the number of times for repetitive operation of RRAM is increased accordingly.

A resistive memory device in the exemplary embodiment has a plurality of ultra-small active regions beyond the limits of a photolithography machine.

Several exemplary embodiments accompanied with figures are described in detail below to further describe the disclosure in details.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIGS. 1A to 9A are schematic top views illustrating methods of manufacturing a resistive memory device according to a first and a second exemplary embodiments.

FIGS. 1B to 9B are schematic cross-sectional views taken along line II-II in the first exemplary embodiment shown in FIGS. 1A to 9A.

FIG. 9B-1 is a schematic cross-sectional view taken along line II-II in the second exemplary embodiment shown in FIG. 9A.

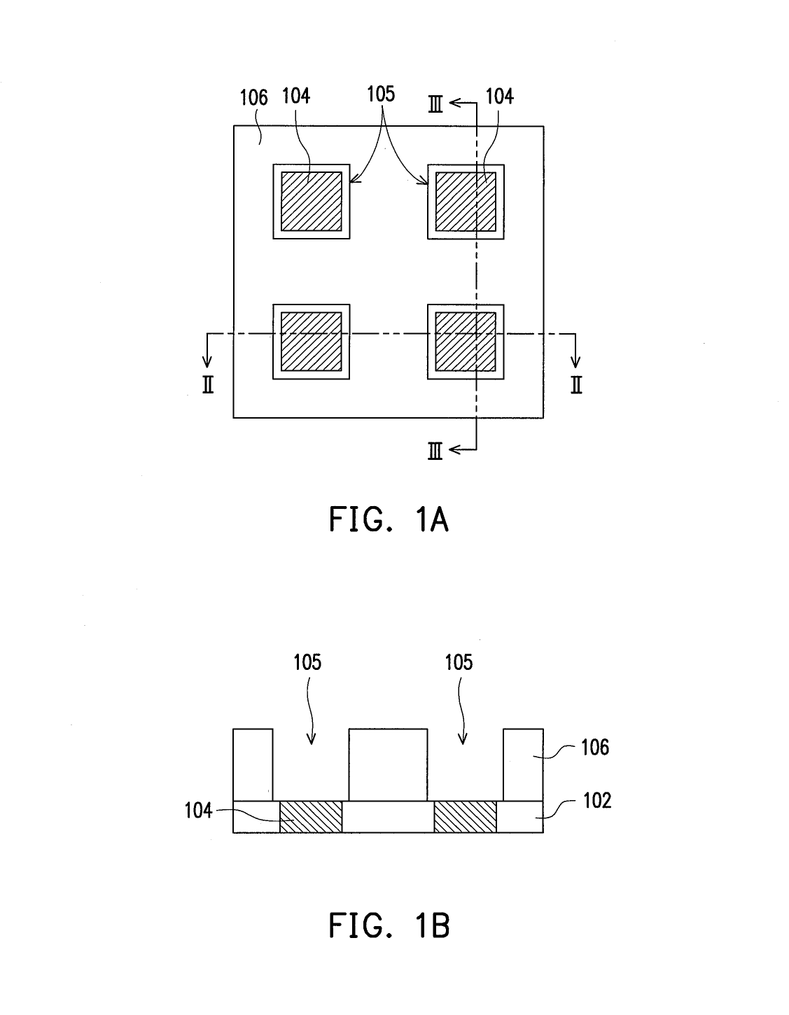

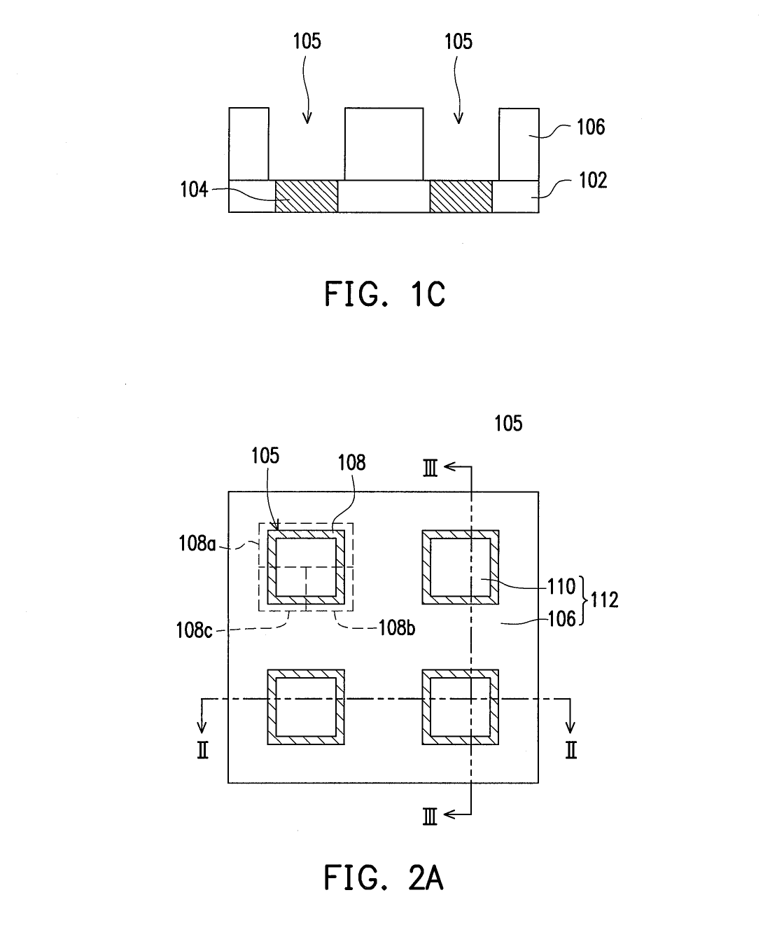

FIGS. 1C to 9C are schematic cross-sectional views taken along line in the first and the second exemplary embodiments shown in FIGS. 1A to 9A.

FIGS. 10A to 18A are schematic top views illustrating methods of manufacturing a resistive memory device according to a third and a fourth exemplary embodiments.

FIGS. 10B to 18B are schematic cross-sectional views taken along line V-V in the third exemplary embodiment shown in FIGS. 10A to 18A.

FIG. 18B-1 is a schematic cross-sectional view taken along line V-V in the fourth exemplary embodiment shown in FIG. 18A.

FIGS. 10C to 18C are schematic cross-sectional views taken along line VI-VI in the third and the fourth exemplary embodiments shown in FIGS. 10A to 18A.

FIGS. 19A to 19B are schematic cross-sectional views illustrating a method of manufacturing a resistive memory device having a three-dimensional (3D) array structure according to a fifth exemplary embodiment.

FIG. 19B-1 is a schematic cross-sectional view illustrating another resistive memory device having a 3D array structure according to the fifth exemplary embodiment.

FIG. 20A is a schematic cross-sectional view illustrating a resistive memory device having a 3D array structure according to a sixth exemplary embodiment.

FIG. 20A-1 is a schematic cross-sectional view illustrating another resistive memory device having a 3D array structure according to the sixth exemplary embodiment.

### DETAILED DESCRIPTION OF DISCLOSED EMBODIMENTS

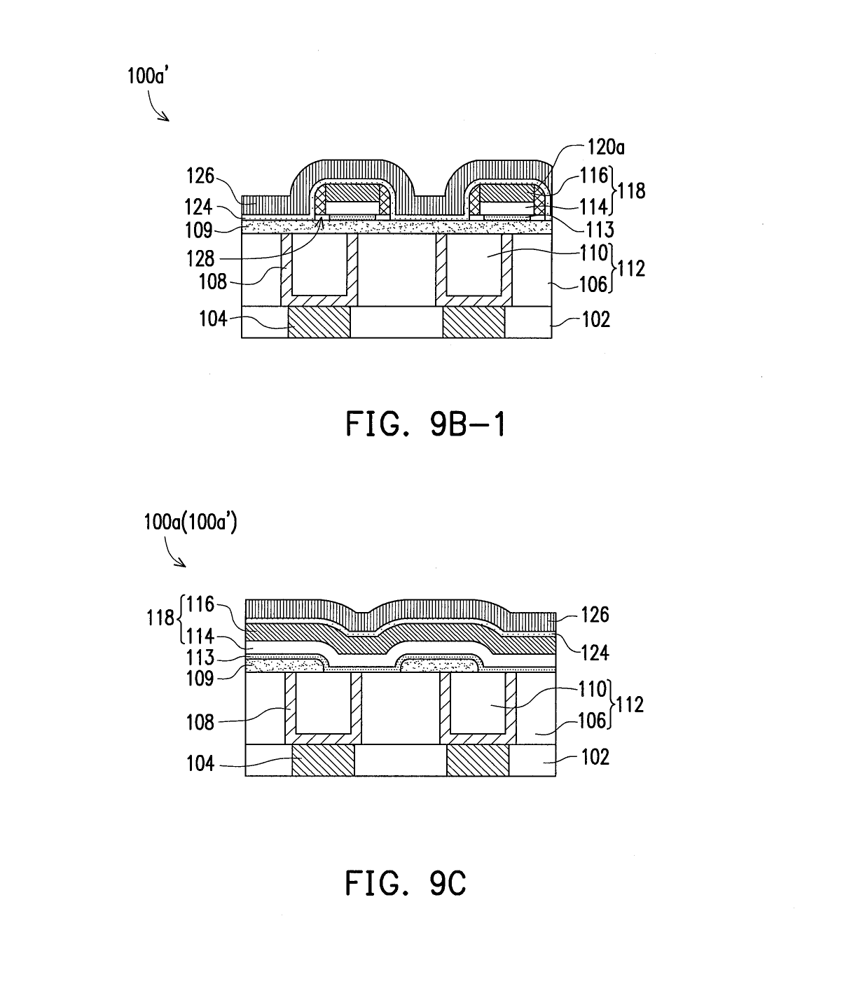

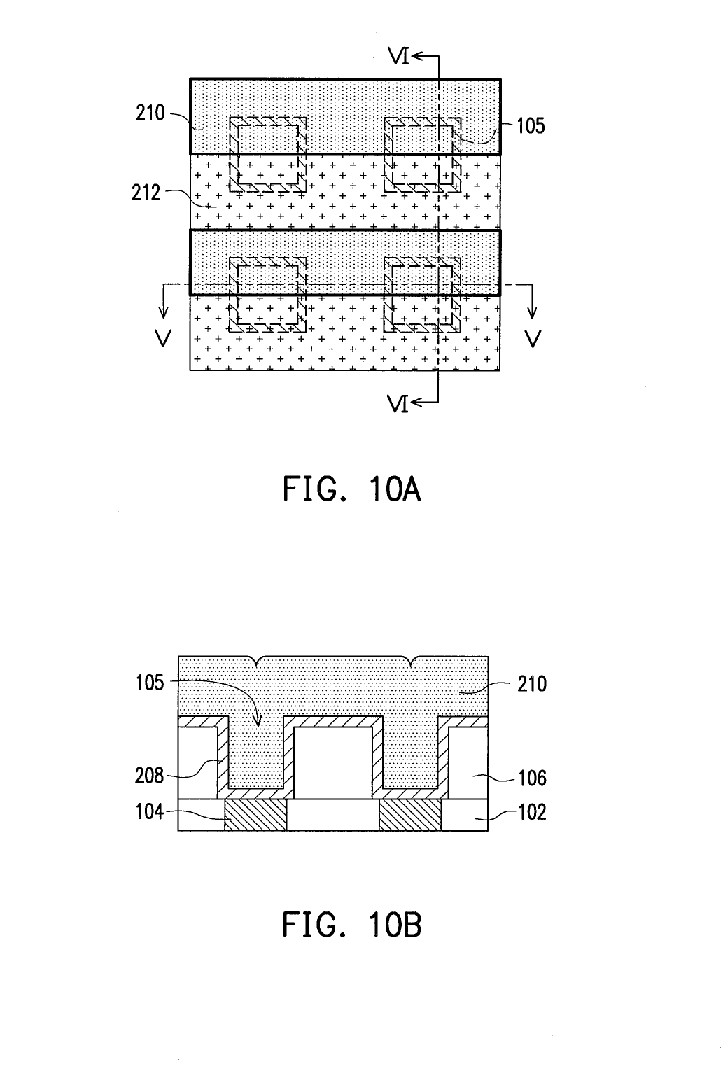

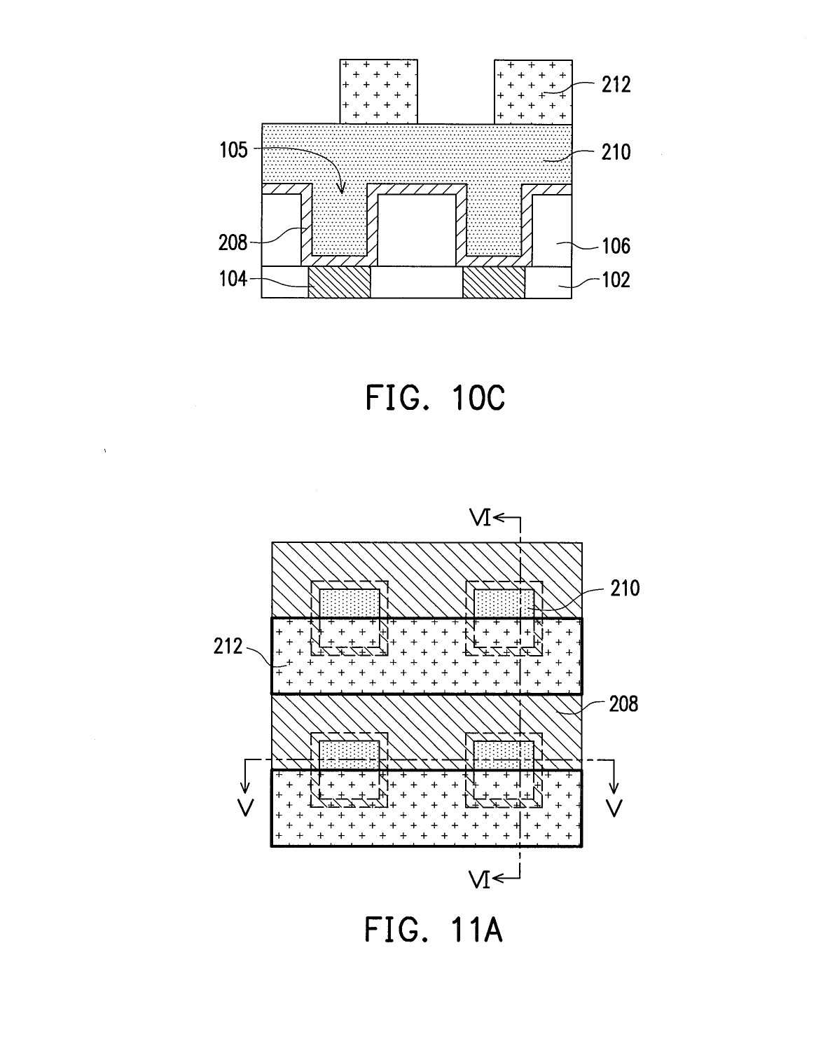

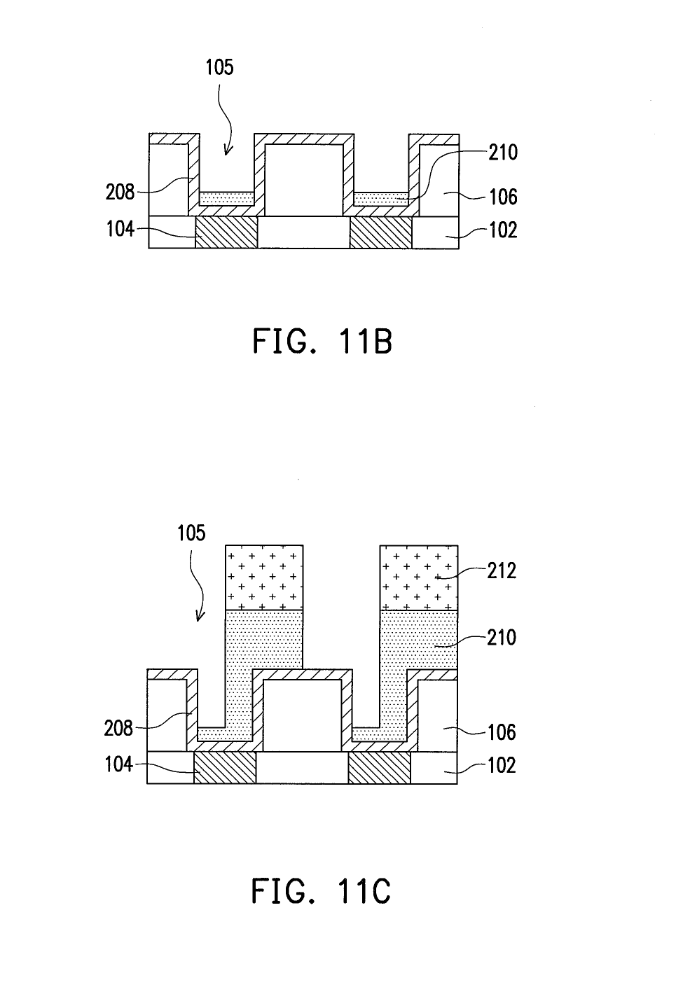

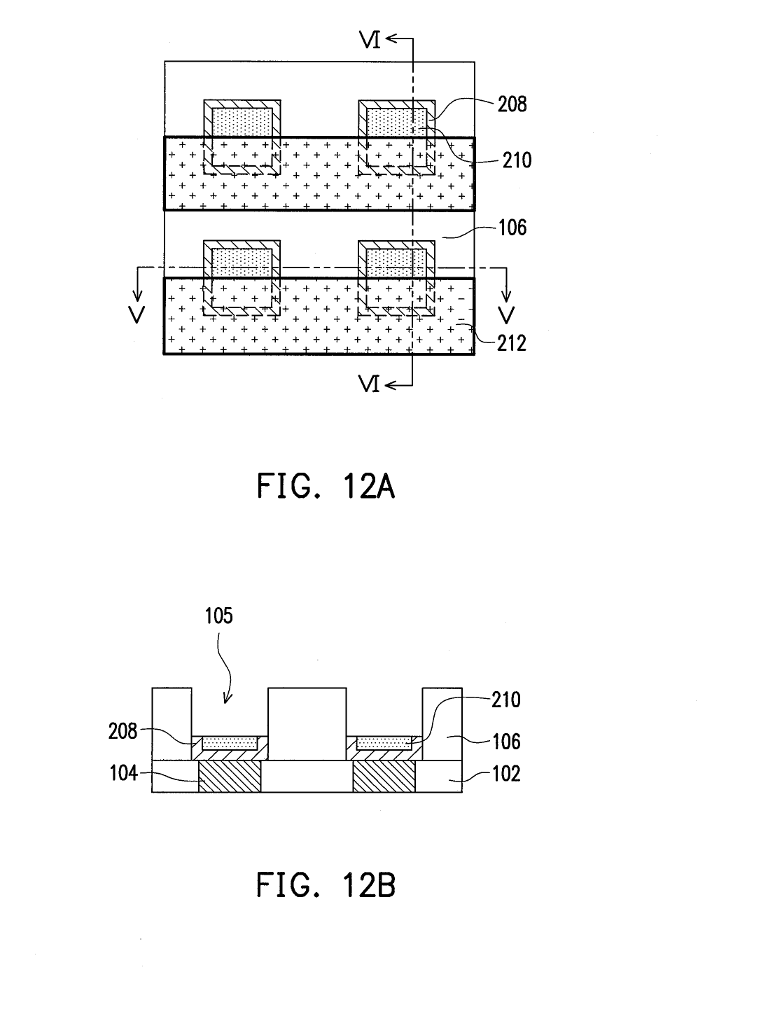

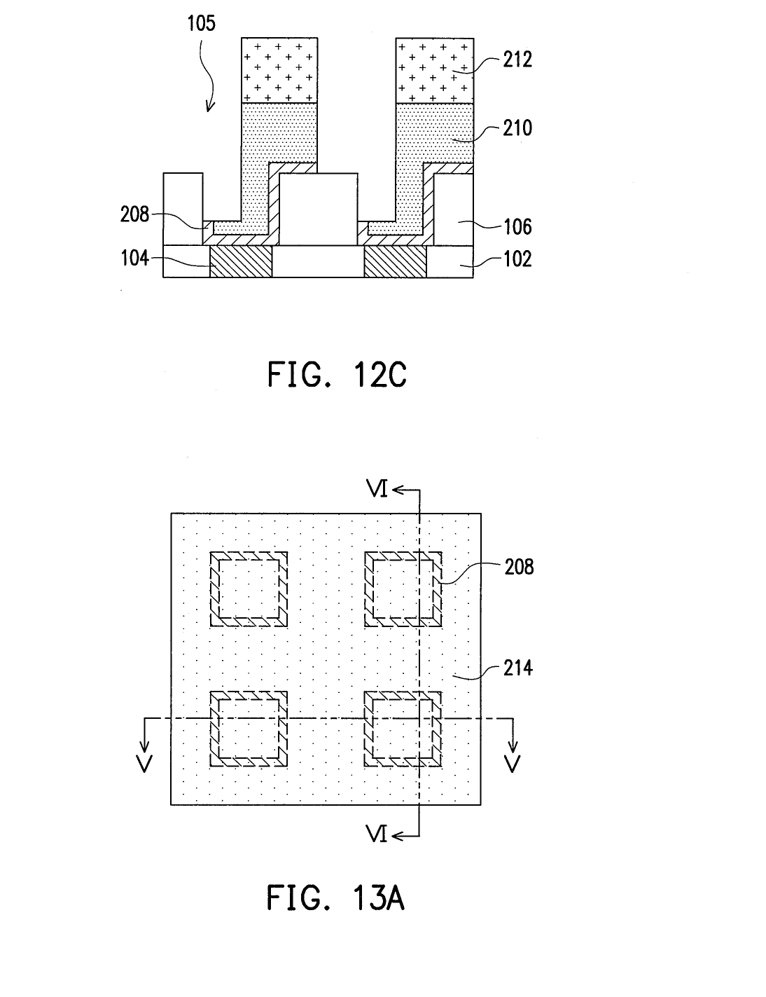

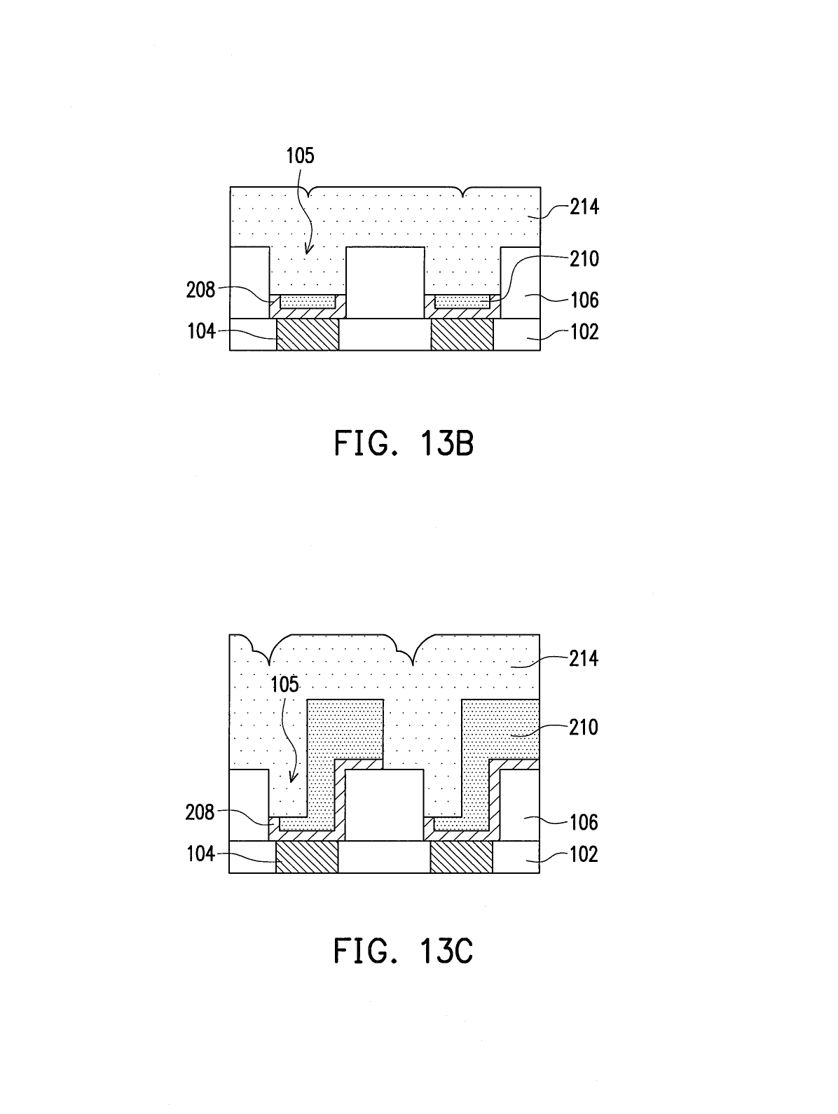

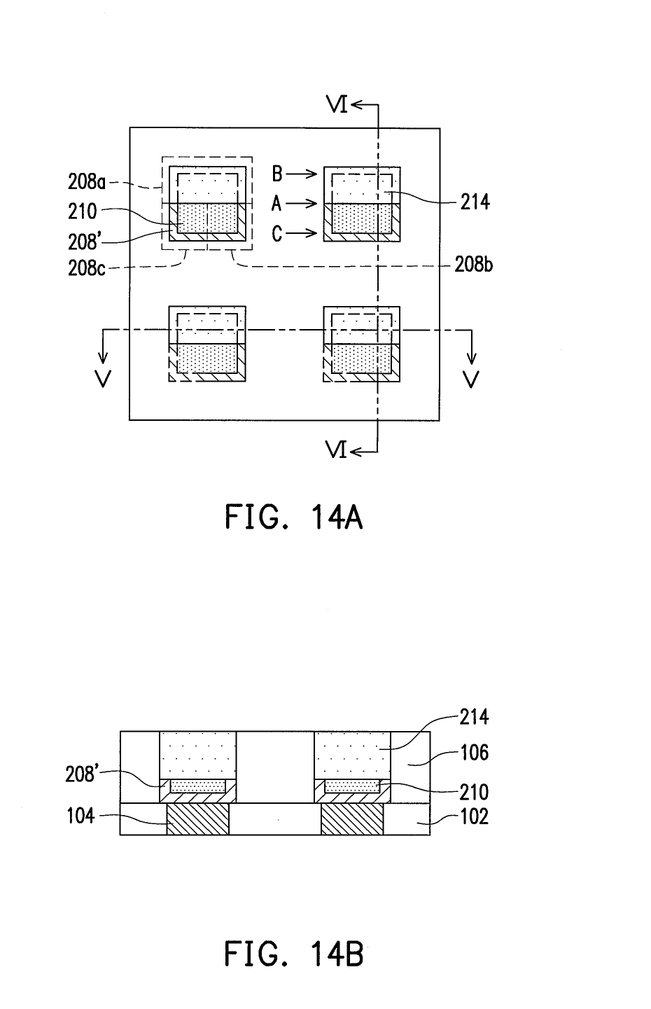

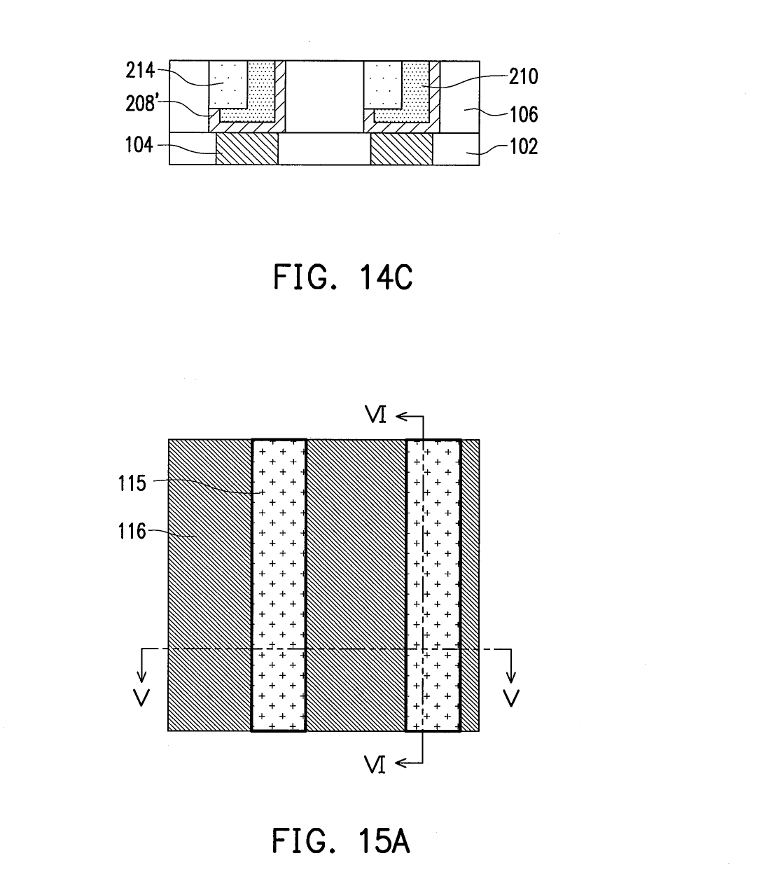

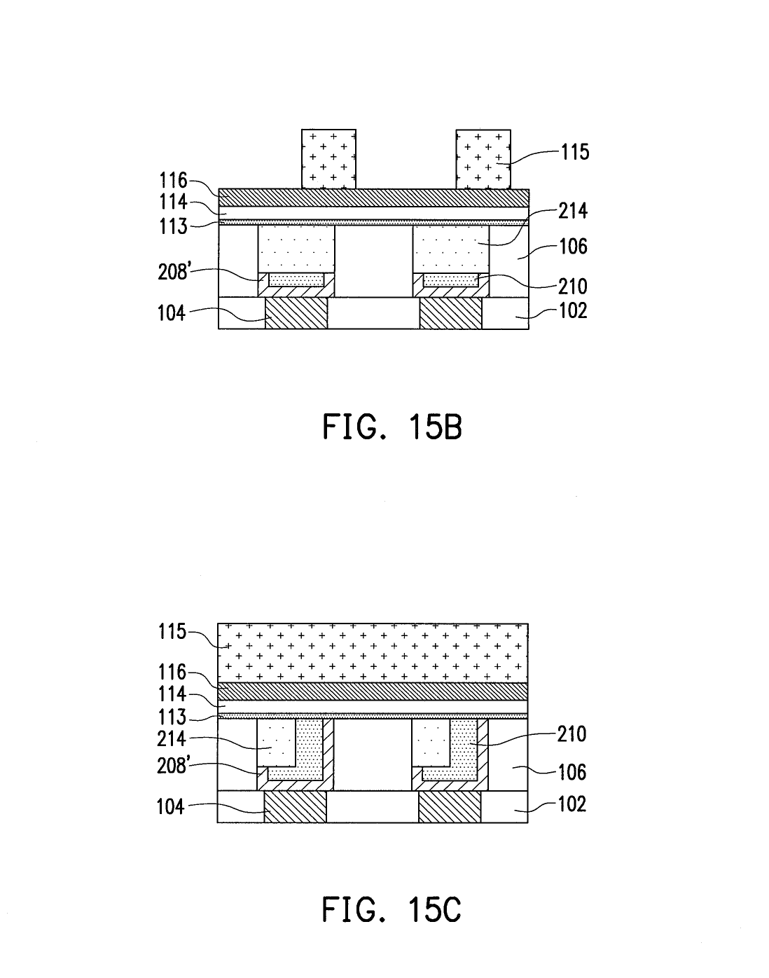

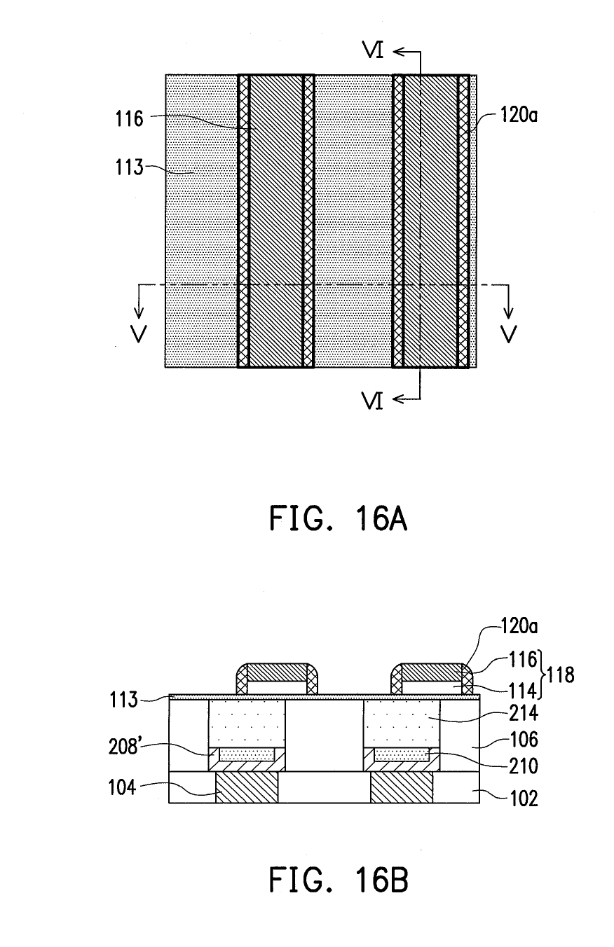

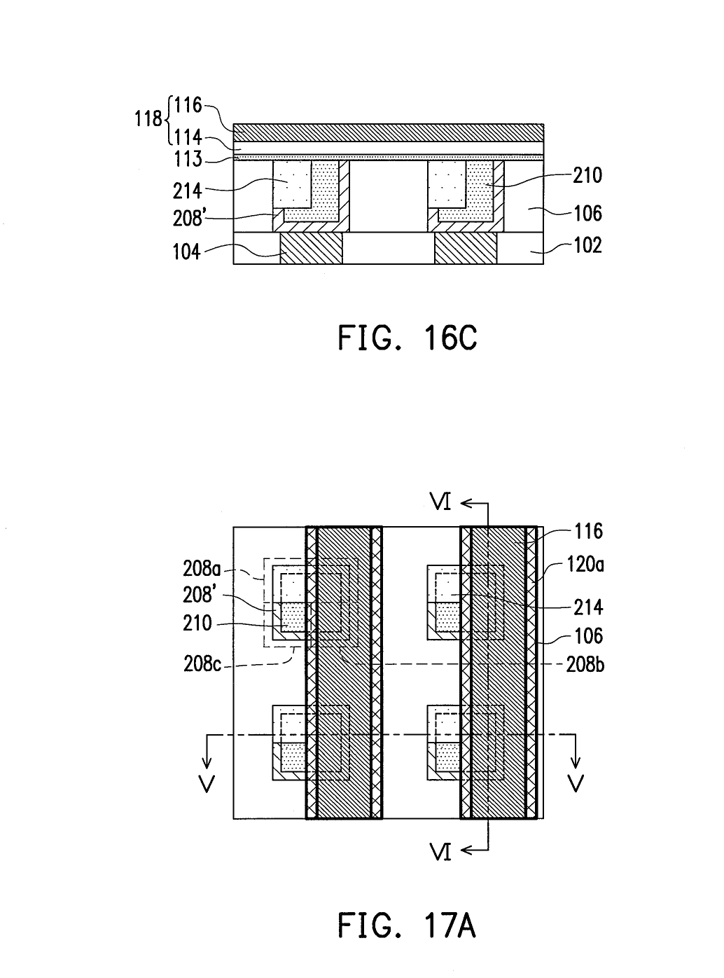

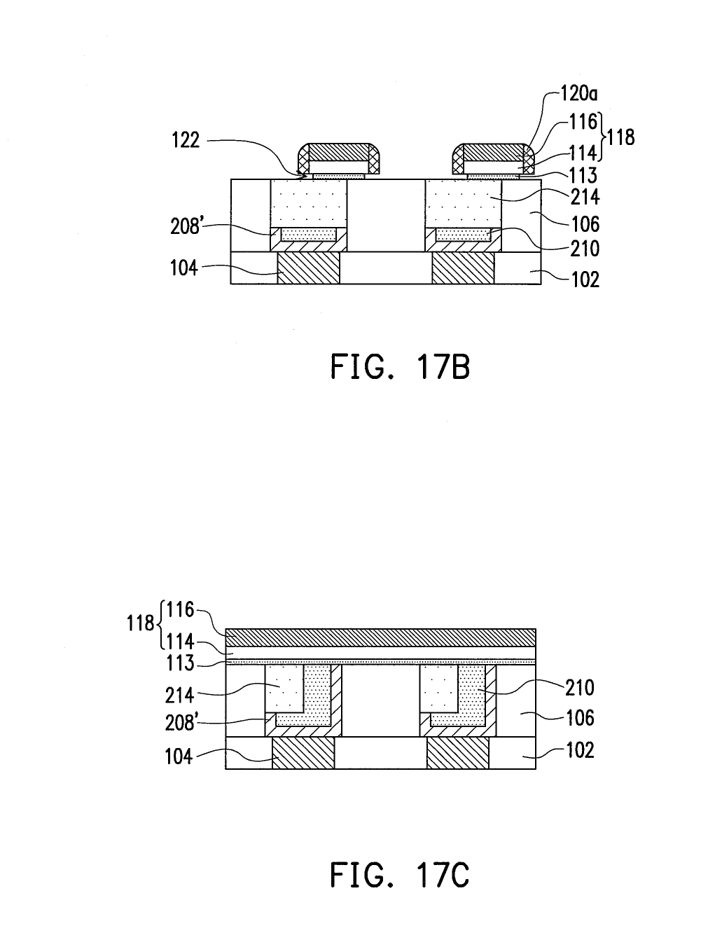

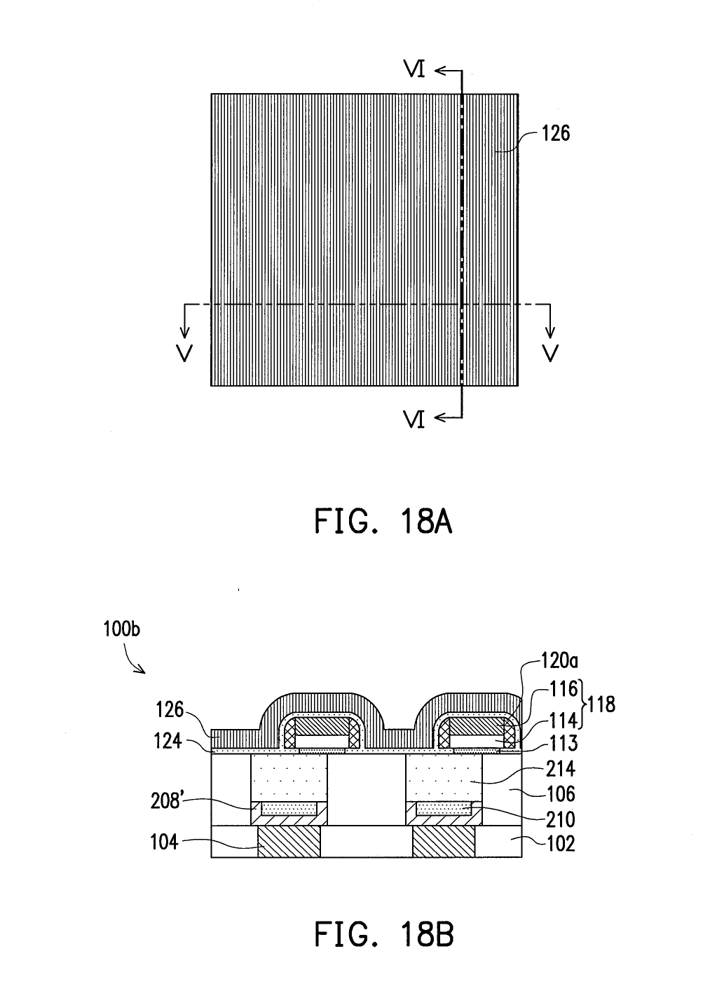

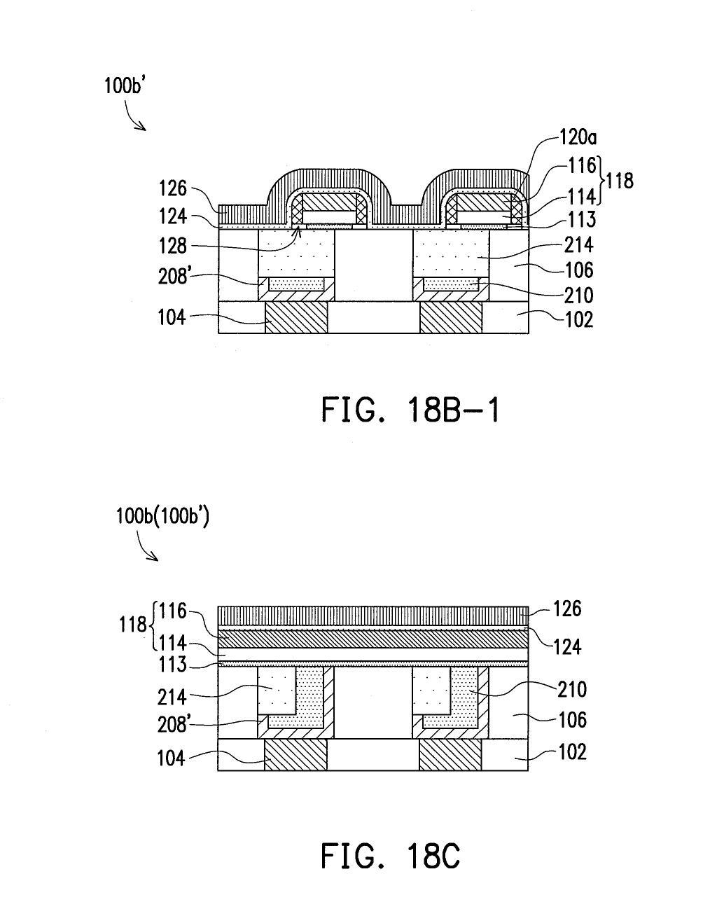

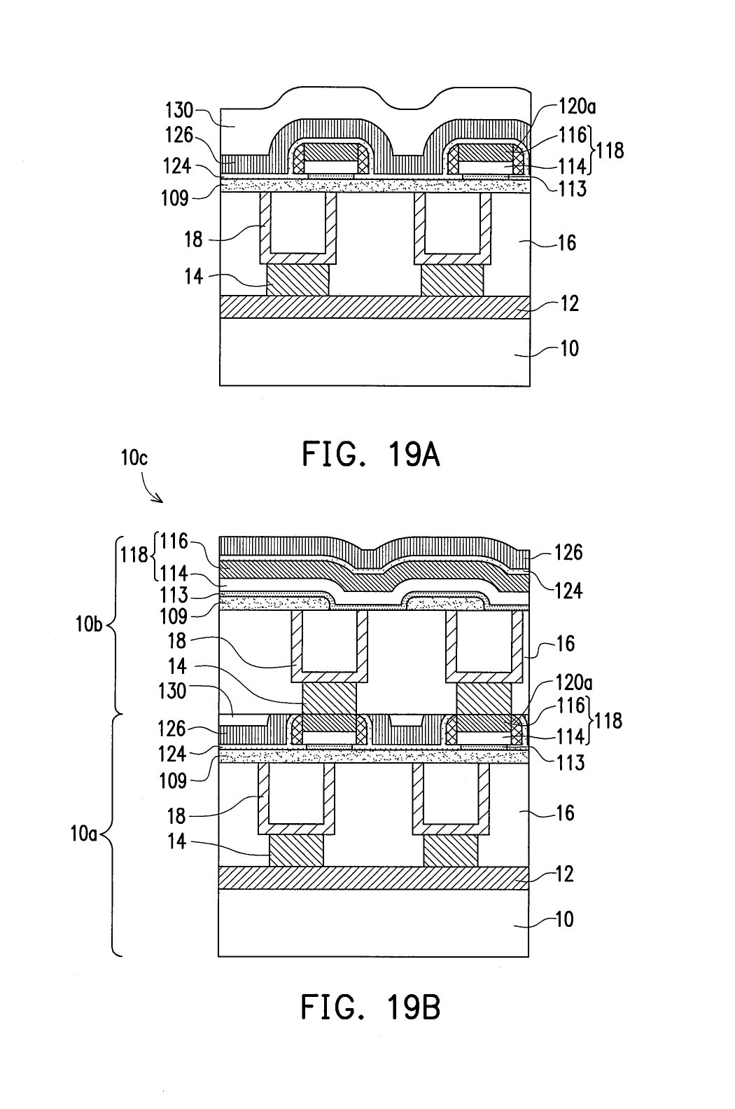

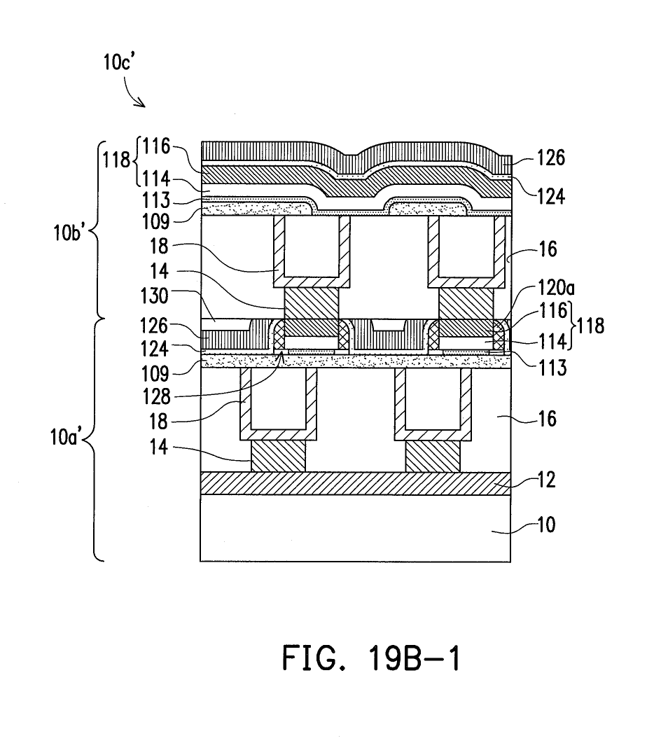

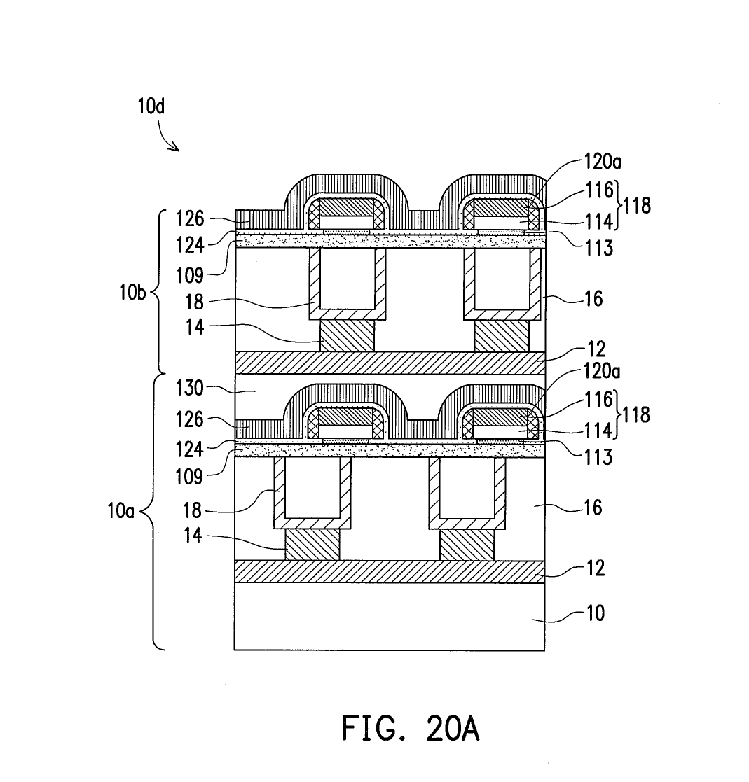

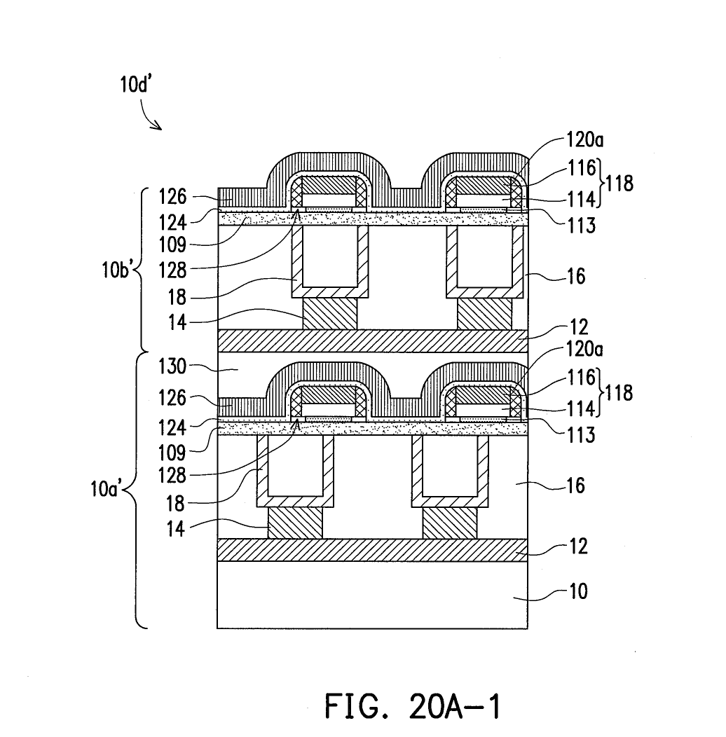

FIGS. 1A to 9A are schematic top views illustrating methods of manufacturing a resistive memory device according to a first and a second exemplary embodiments. FIGS. 1B to 9B are schematic cross-sectional views taken along line II-II in the first exemplary embodiment shown in FIGS. 1A to 9A. FIG. 9B-1 is a schematic cross-sectional view taken along line II-II in the second exemplary embodiment shown in FIG. 9A. FIGS. 1C to 9C are schematic cross-sectional views taken along line in the first and the second exemplary embodiments shown in FIGS. 1A to 9A.

Referring to FIGS. 1A, 1B, and 1C, a plurality of bottom electrodes 104 is formed in an insulating layer 102. The insulating layer 102 can be formed on a substrate (not shown). A material of the insulating layer 102 includes SiOx, SiNx, or SiOxNy, where x, y can be any possible number in chemical stoichiometry. A method of forming the bottom electrodes 104 includes forming a plurality of via openings (not shown) in the insulating layer 102. Thereafter, a bottom electrode material layer (not shown) is formed on the insulating layer 102. The bottom electrode material layer covers a top surface of the insulating layer 102 and is filled into the via openings. Next, the bottom electrode material layer outside the via openings is removed. A material of the bottom electrode material layer is constituted by a single material layer or two or more layers of material layers. A material of the bottom electrode material layer includes a metal, an alloy, a metal nitride, a metal silicide, or a combination thereof. For example, TiW, TiN, Al, Cu, TaN, Ti, or a combination thereof A method of forming the bottom electrode material layer is, for instance, an atomic layer deposition (ALD), a chemical vapor deposition (CVD), a physical vapor deposition (PVD), or an electroless plating method. The thickness of the bottom electrode material layer ranges from 50 nm to 300 nm, for example.

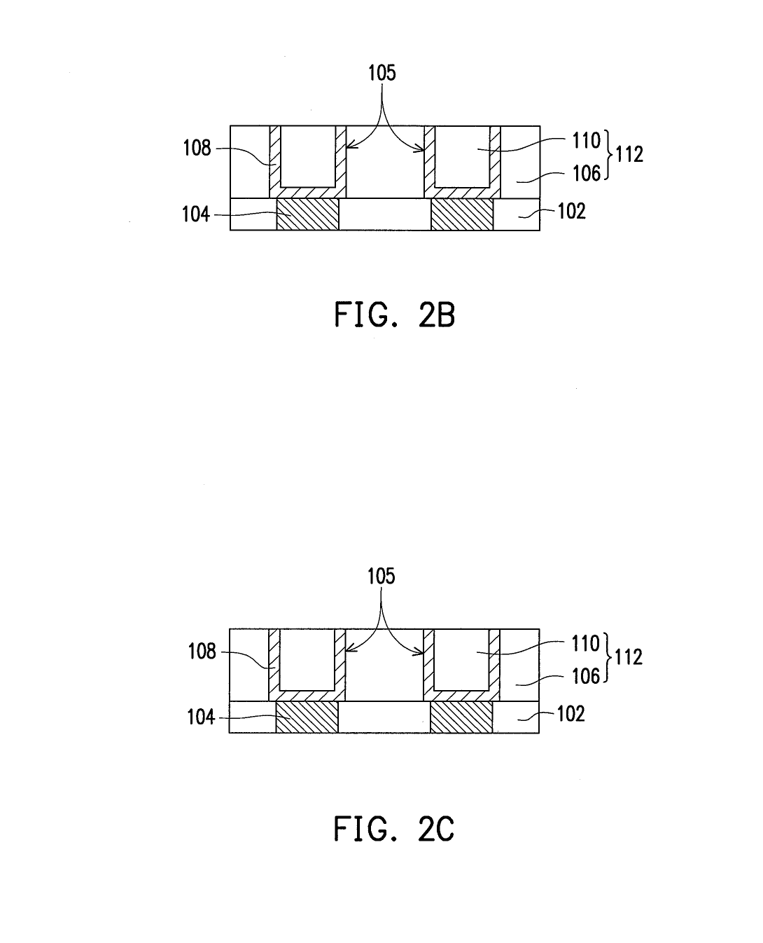

Afterwards, referring to FIGS. 2A, 2B, and 2C, an insulating layer 112 is formed on the insulating layer 102 and a plurality of cup-shaped electrodes 108 is formed in the insulating layer 112. A bottom portion of each of the cup-shaped electrodes 108 is connected to the corresponding bottom electrode 104. A method of forming the insulating layer 112 and the cup-shaped electrodes 108 is described in the following. Firstly, referring to FIGS. 1A, 2A, and 3A, an insulating layer 106 having a plurality of openings 105 is formed on the insulating layer 102. Each of the openings 105 exposes the corresponding bottom electrode 104. A side length of each of the openings 105 is, for example, 480 nm. A material of the insulating layer 106 includes SiOx, SiNx, SiOxNy, or other similar insulating materials, where x, y can be any possible number in chemical stoichiometry. A method of forming the insulating layer 106 is a CVD, for example. Subsequently, a cup-shaped electrode material layer (not shown) is formed on the insulating layer 102 to cover the insulating layer 106, a plurality of sidewalls of the openings 105, and the bottom electrodes 104. The openings 105 are then filled with an insulating material layer to cover the cup-shaped electrode material layer above the insulating layer 106. A material of the cup-shaped electrode material layer is constituted by a single material layer or two or more layers of material layers. A material of the cup-shaped electrode material layer includes a metal, a metal nitride, or a metal silicide, for example, TiN, Ti, TaN, Ta, WN, W, Pt, Cu, or a stacked layer having a combination thereof The thickness of the cup-shaped electrode material layer ranges from 1 nm to 100 nm, for instance, 5 nm. Later, the insulating material layer is planarized to remove the insulating material layer outside the openings 105. The insulating material layer remained inside the openings 105 is an insulating layer 110. The cup-shaped electrode material layer above the insulating layer 106 is then removed to form a cup-shaped electrode 108 in each of the openings 105. The insulating layer 106 and the insulating layer 110 constitute the insulating layer 112. The insulating layer 110 and the insulating layer 106 can be made of the same or different materials, for example, SiOx, SiNx, or SiOxNy, where x, y can be any possible number in chemical stoichiometry. An area surrounded by each of the cup-shaped electrodes 108 has a first area 108a, a second area 108b, and a third area 108c. In an exemplary embodiment, areas of the first area 108a, the second area 108b, and the third area 108c are respectively ½, ¼, and ¼ of an area surrounded by the cup-shaped electrode 108, for example.

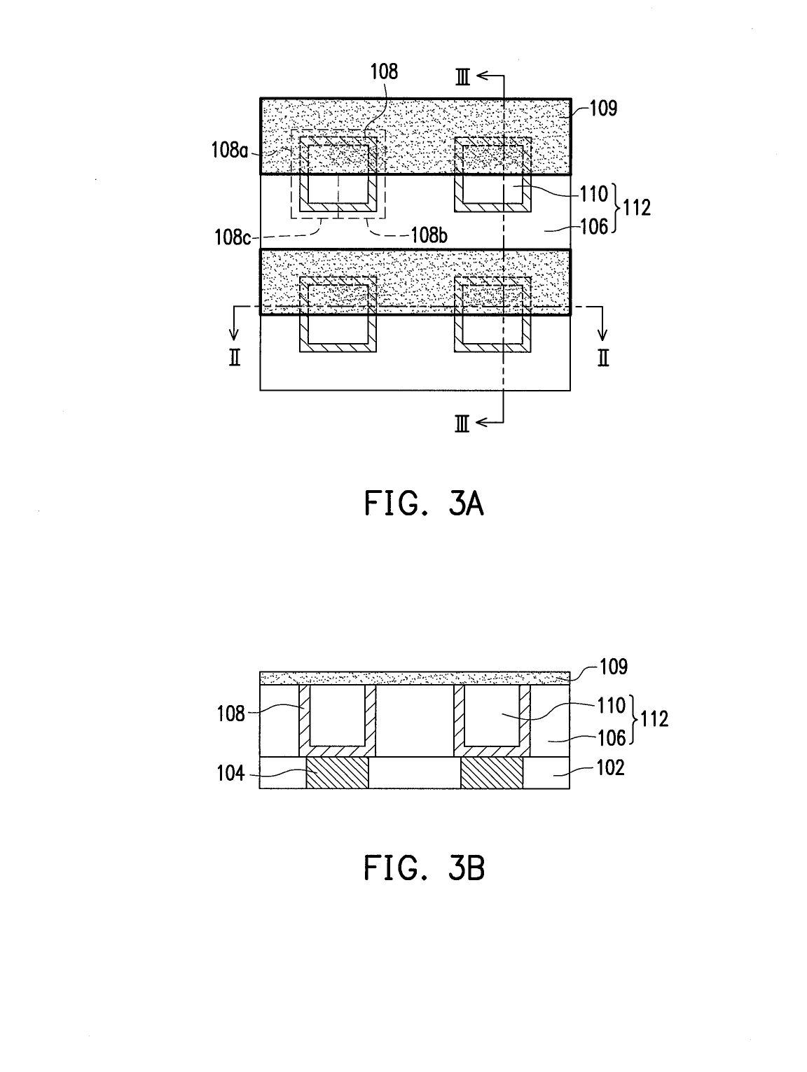

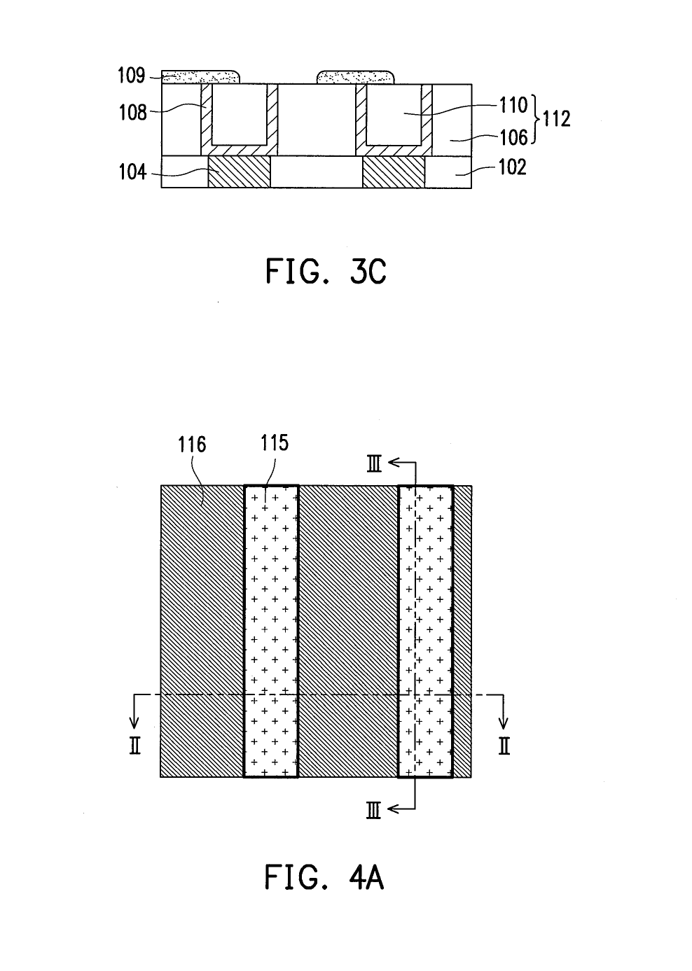

Referring to FIGS. 3A, 3B, and 3C, a plurality of cover layers 109 is formed on the insulating layer 102. Each of the cover layers 109 extends along a first direction to cover the first area 108a surrounded by the corresponding cup-shaped electrode 108 and the insulating layer 112 at the periphery of the first area 108a so as to expose the second area 108b and the third area 108c surrounded by the cup-shaped electrode 108. A plurality of sidewalls of the cover layers 109 can have a rounding shape. A method of forming the cover layers 109 includes forming a cover material layer (not shown) on the insulating layer 102. A photolithography process and an etching process are performed to remove a portion of the cover material layer. A material of the cover material layer includes SiNx, SiOx, or SiOxNy, where x, y can be any possible number in chemical stoichiometry. A method of forming the cover material layer includes performing an atomic layer deposition or a CVD. The thickness of the cover material layer ranges from 10 nm to 200 nm, for example. The etching process to remove the portion of the cover material layer is an isotropic etching process, for instance.

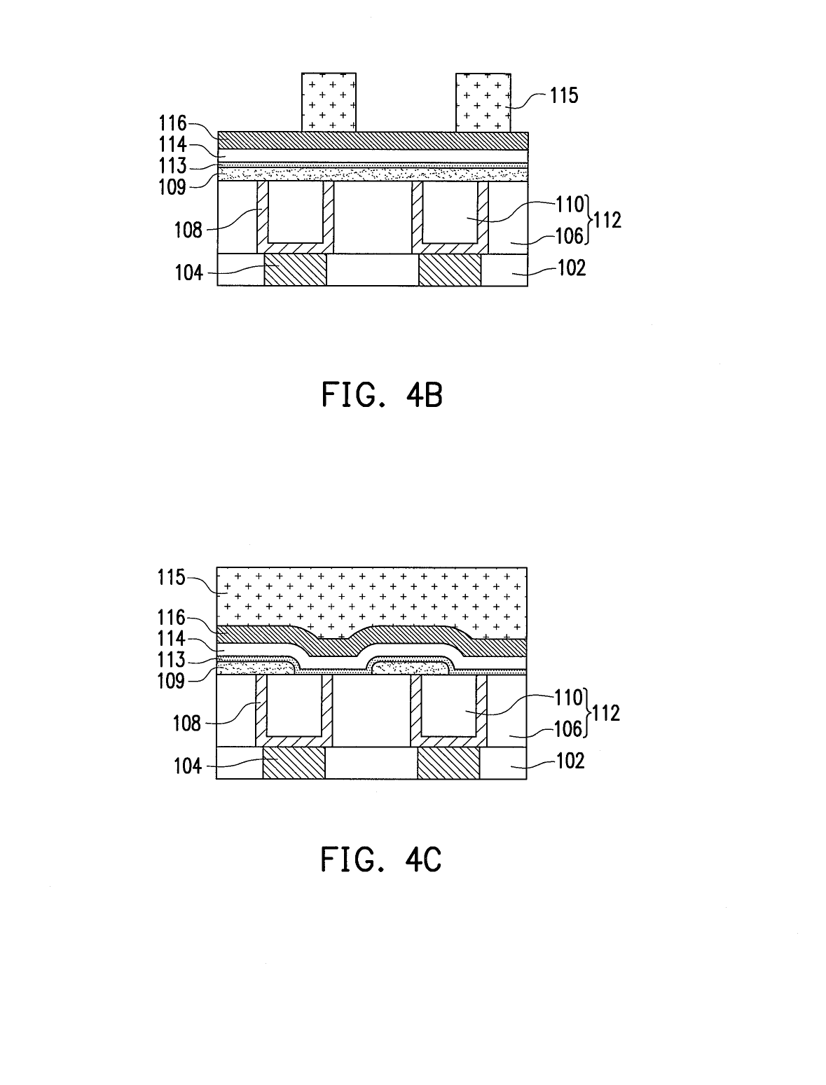

Afterwards, referring to FIGS. 4A, 4B, and 4C, a sacrificial layer 113, a dielectric layer 114, and a top electrode layer 116 are formed on the insulating layer 112. The sacrificial layer 113 is manufactured using a material different from that of the dielectric layer 114. Moreover, the sacrificial layer 113 is manufactured using a material different from that of the top electrode layer 116. A material of the sacrificial layer 113 can be a metal oxide, for example, NiOx or CoOx (x is any possible number in chemical stoichiometry), or basically any material having a high selectivity (larger than 30), etchable by plasma in CO/NH₃ environment, and almost not etchable by a plasma based on fluorine or chlorine environment. In one exemplary embodiment, a material of the sacrificial layer 113 is a metal oxide. A method of forming the metal oxide includes the following. For example, a metal layer is first deposited and then oxidized into a metal oxide; or a metal oxide is formed directly using a sputtering method. The thickness of the sacrificial layer 113 ranges from 3 nm to 50 nm, for example. A material of the dielectric layer 114 includes SiOx, SiNx, or SiOxNy, where x, y are any possible number in chemical stoichiometry. A method of forming the dielectric layer 114 is, for instance, a CVD or an ALD. The top electrode layer 116 and the bottom electrodes 104 can be made of the same or different materials. The top electrode layer 116 can be constituted by a single material layer or two or more layers of different material layers. A material of the top electrode layer 116 is a metal, an alloy, a metal nitride, a metal silicide, or a metal oxide. A material of the top electrode layer 116 is, for example, TiW, TiN, Al, TaN, Ta, Ti, WN, W, or a combination thereof. A method of forming the top electrode layer 116 includes a CVD or a PVD. The thickness of the top electrode layer 116 ranges from 10 nm to 200 nm, for example.

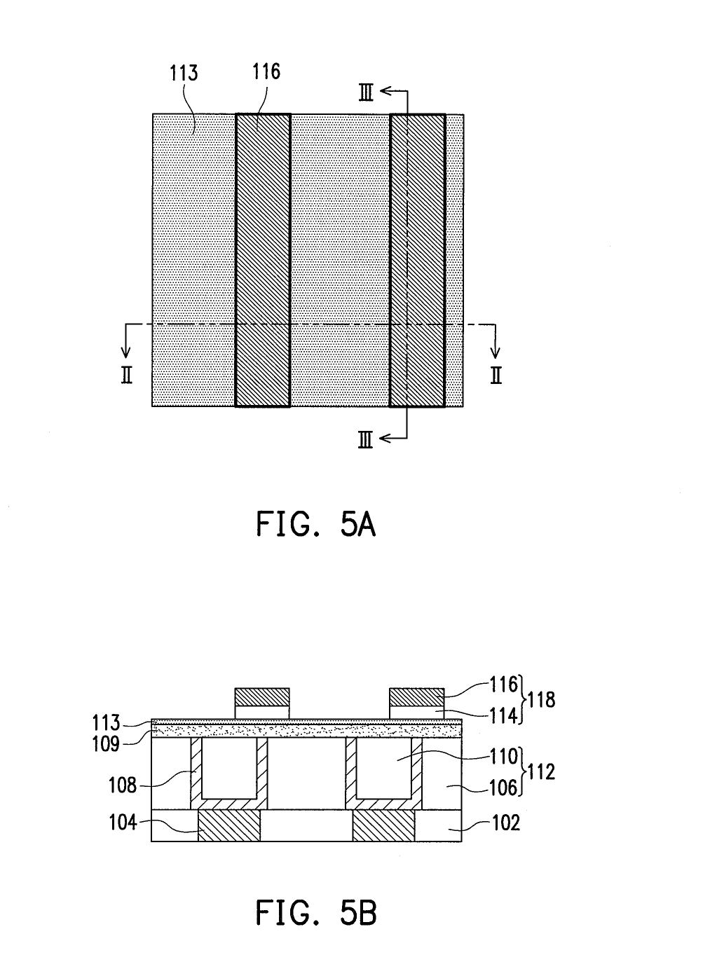

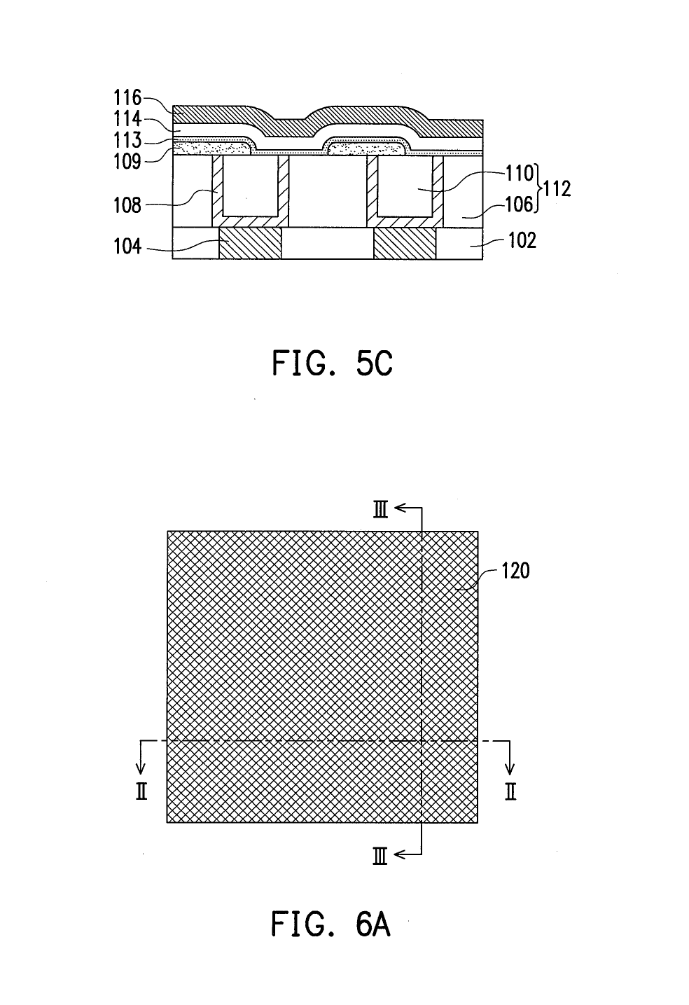

Referring to FIGS. 5A, 5B, and 5C, the top electrode layer 116 and the dielectric layer 114 are patterned to form a plurality of stacked structures 118. The stacked structures 118 extend along a second direction. In one exemplary embodiment, the second direction and the first direction are substantially perpendicular to each other. Each of the stacked structures 118 covers on a top of the second area 108b surrounded by the cup-shaped electrode 108 and a top of the corresponding portion of the cover layer 109. A method of patterning the top electrode layer 116 and the dielectric layer 114 is illustrated below. For instance, a photolithography process is first performed. That is, a photoresist layer 115 is formed on the top electrode layer 116 (as shown in FIGS. 1D, 2D, and 3D). An anisotropic etching process is then performed to remove the top electrode layer 116 and the dielectric layer 114 not covered by the photoresist layer 115. The photoresist layer 115 is later removed. The sacrificial layer 113 is made of a material different from those of the dielectric layer 114 and the top electrode layer 116. As a consequence, an etchant having a relatively high etching selectivity of the sacrificial layer 113 to the dielectric layer 114 and between the sacrificial layer 113 and the top electrode layer 116 is selected in the etching process, so that the sacrificial layer 113 can be used as an etch stop layer during the etching process to prevent the insulating layer 112 and the cup-shaped electrodes 108 below the sacrificial layer 113 from being damaged by etching due to overetch. An etching selectivity between the sacrificial layer 113 and the dielectric layer 114 is, for instance, larger than 30. An etching selectivity of the sacrificial layer 113 to the top electrode layer 116 is, for instance, larger than 30. In one exemplary embodiment, a material of the sacrificial layer 113 is NiOx; a material of the dielectric layer 114 is SiOx; a material of the top electrode layer 116 is TiN. An etching process can uses a fluorine (F)-based plasma or a chlorine (Cl)-based plasma by adopting fluorine and nitrogen or chlorine and boron trichloride as a gas source, for example. The two kinds of plasma can be applied collaboratively.

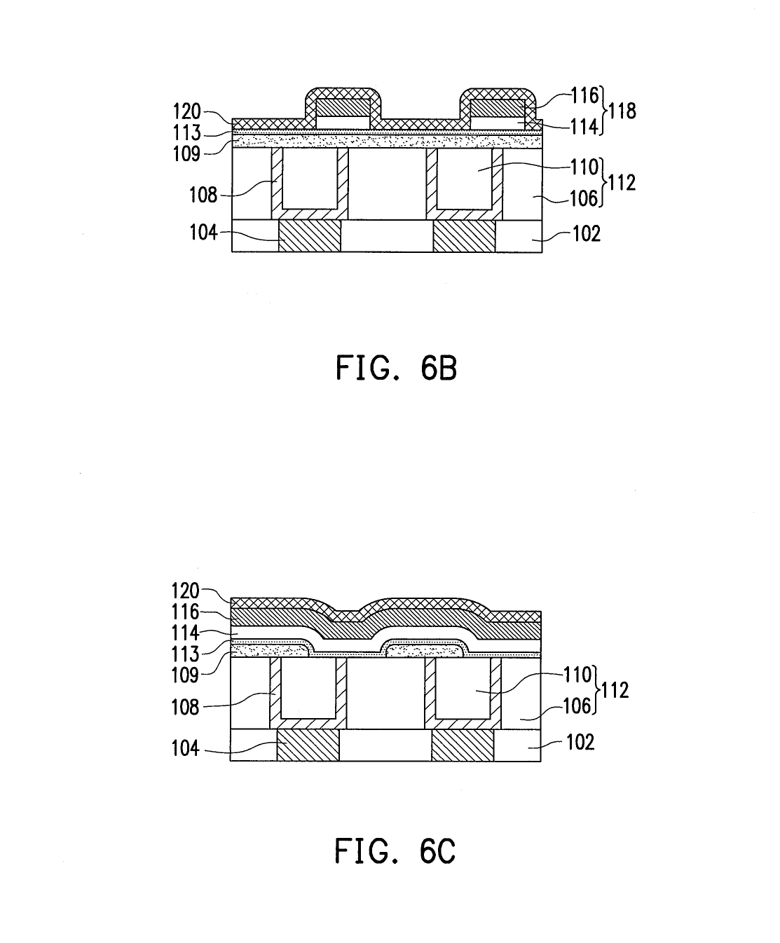

Referring to FIGS. 6A, 6B, and 6C, a conductive spacer material layer 120 is formed on the sacrificial layer 113 and the stacked structures 118. A material of the conductive spacer material layer 120 is different from that of the sacrificial layer 113. The conductive spacer material layer 120 can be constituted by a single material layer or two or more layers of material layers. A material of the conductive spacer material layer 120 is, for instance, TaN, TiN, WN, TiW, Ti, Ta, W, Ni, Co, Zr, Ru, RuOx, Pt, Al, Cu, or a stacked layer of the same, where x can be any possible number in chemical stoichiometry. A method of forming the conductive spacer material layer 120 includes a PVD method, for example, a sputtering method, or various CVD methods. In an exemplary embodiment, the conductive spacer material layer 120 and the sacrificial layer 113 are formed conformally with the stacked structures 118, where the thickness thereof ranges from 1 nm to 100 nm and is, for instance, 5 nm.

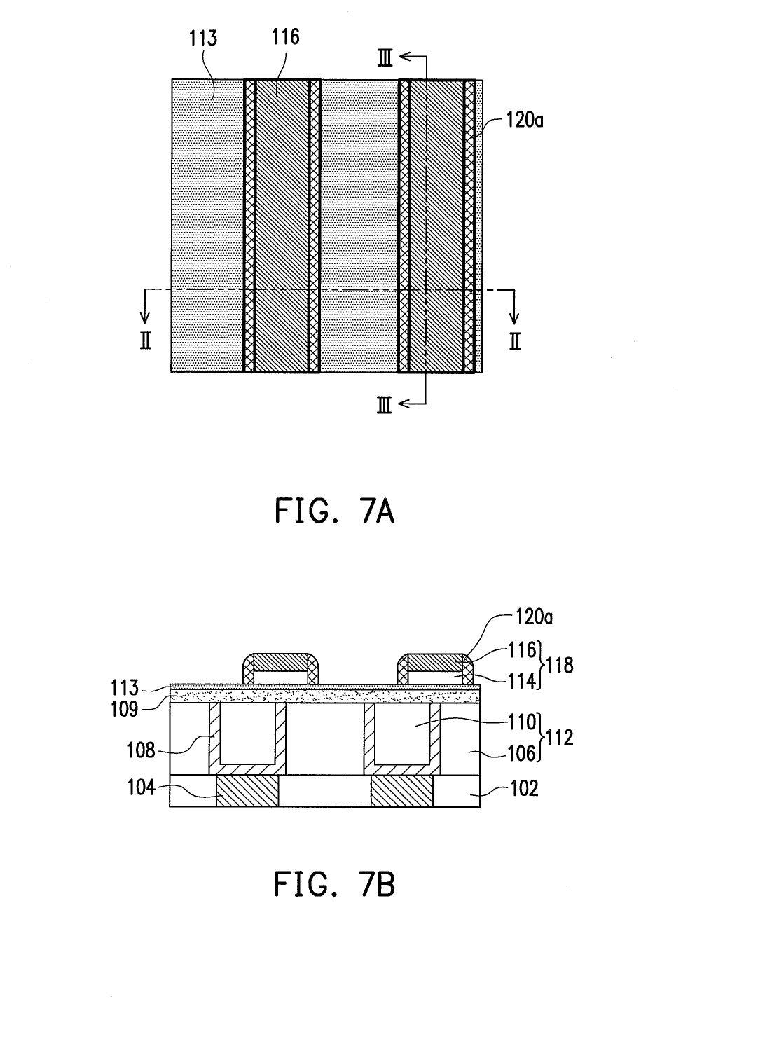

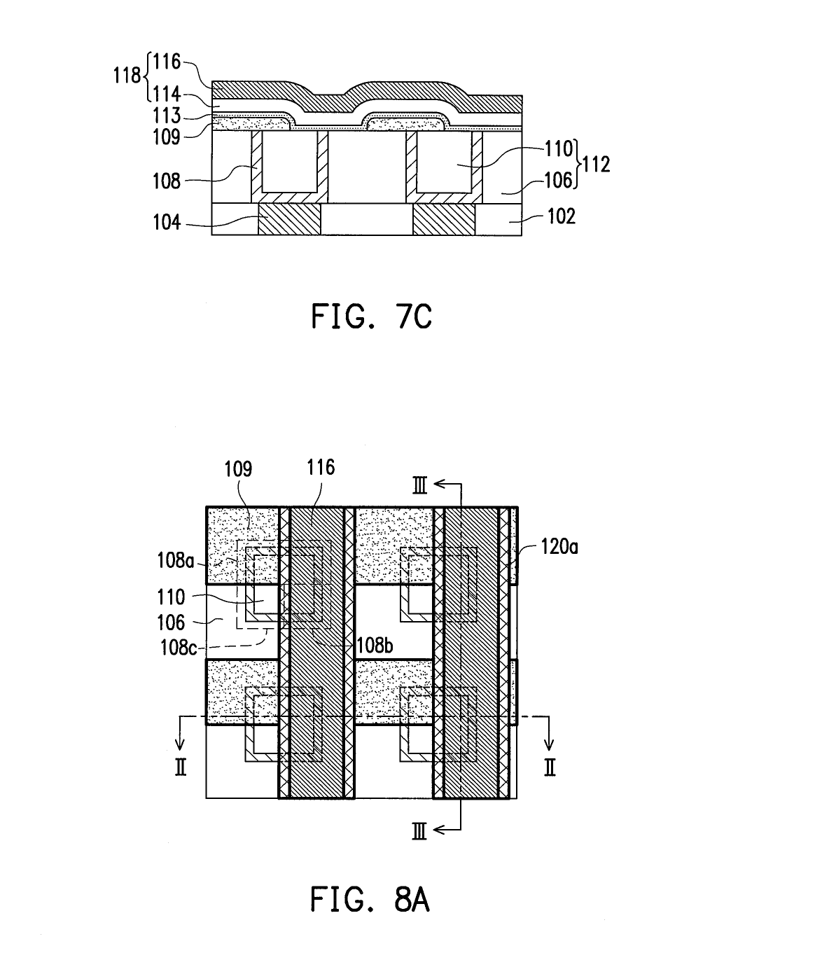

Subsequently, referring to FIGS. 7A, 7B, and 7C, by using the sacrificial layer 113 as the etch stop layer, an anisotropic etching process is performed to remove a portion of the conductive spacer material layer 120 so as to form a plurality of conductive spacers 120a. Since different materials are utilized in the manufacture of the conductive spacer material layer 120 and the sacrificial layer 113, an etchant having a relatively high etching selectivity of the conductive spacer material layer 120 to the sacrificial layer 113 is selected in the etching process, so that the sacrificial layer 113 can be as an etch stop layer during the etching process to prevent the insulating layer 112 and the cup-shaped electrodes 108 below the sacrificial layer 113 from being damaged by etching due to overetch. An etching selectivity of the conductive spacer material layer 120 to the sacrificial layer 113 is, for instance, larger than 30. In one exemplary embodiment, a material of the conductive spacer material layer 120 is Ti; a material of the sacrificial layer 113 is NiOx. An etching process can uses an Cl-based plasma by adopting chlorine and boron trichloride as a gas source, for example. It should be noted that a size of the conductive spacers 120a formed is not defined by a photolithography process and an etching process, but by a deposition process and an etching process, where the size can be reduced beyond the limits of a photolithography machine.

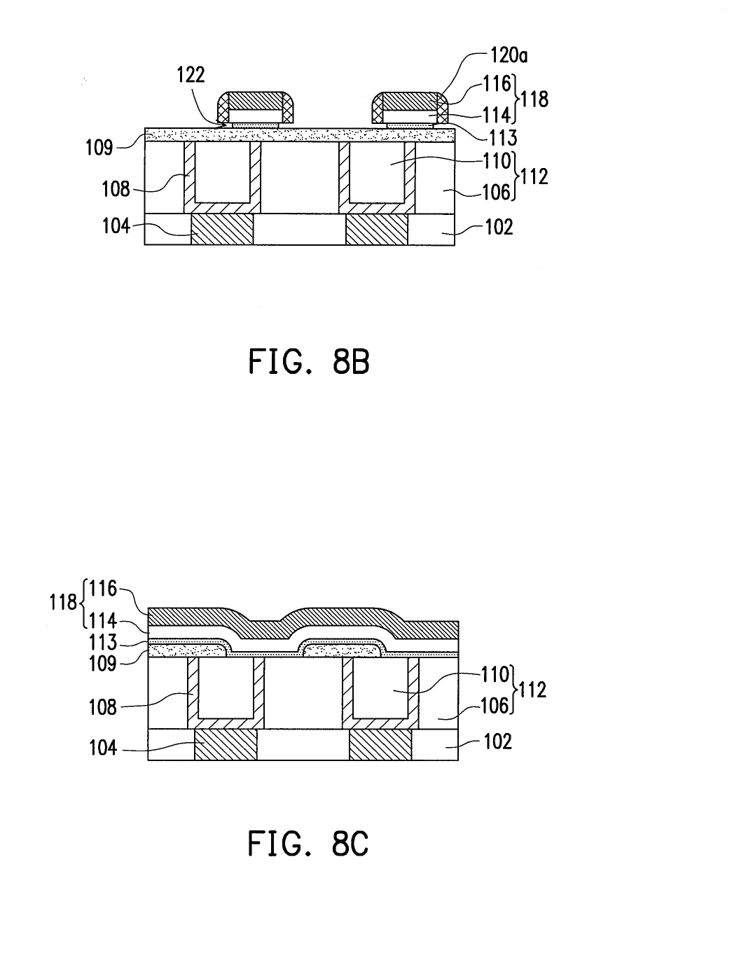

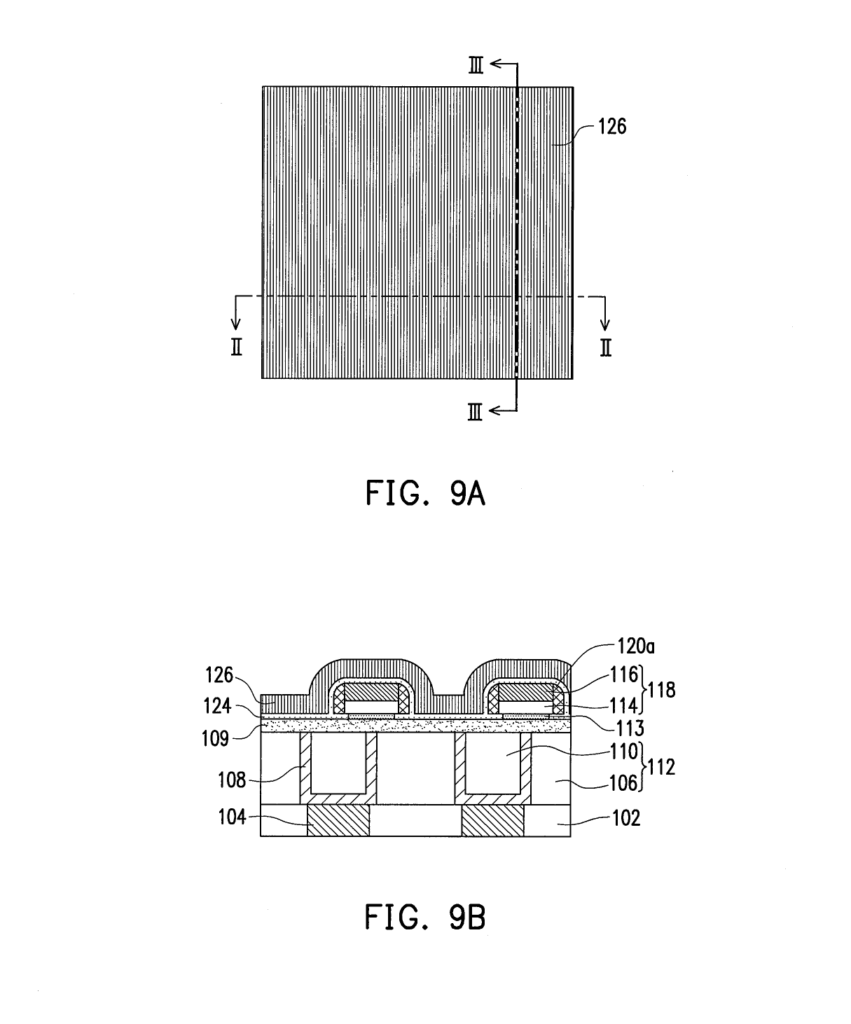

Next, referring to FIGS. 8A, 8B, and 8C, by using the conductive spacers 120a and the stacked structures 118 as a mask, a portion of the sacrificial layer 113 is removed to expose a surface of a portion of the cover layer 109 and the third area 108c surrounded by the cup-shaped electrode 108 and form an undercut 122 (or referred as a recess) below the conductive spacers 120a and the stacked structures 118. A method of removing a portion of the sacrificial layer 113 includes the following. An anisotropic etching process is first performed to remove the sacrificial layer 113 not covered by the conductive spacers 120a and the stacked structures 118. Thereafter, an isotropic etching process is then carried out to remove a portion of the sacrificial layer 113 below the conductive spacers 120a and the stacked structures 118 to form the undercut 122. The sacrificial layer 113 is made of a material different from those of the insulating layer 112 and the cup-shaped electrode layer 108. As a consequence, the insulating layer 112 and the cup-shaped electrode layer 108 can be applied as the etch stop layer in the etching process of the sacrificial layer 113 In one exemplary embodiment, a material of the sacrificial layer 113 is NiOx; the anisotropic etching process applies a CO/NH₃ plasma, for example; the isotropic etching process applies a CO/NH₃ plasma, for instance, but adjusts a bias voltage of a silicon substrate to perform an isotropic plasma etching process.

Subsequently, referring to FIGS. 9A, 9B, and 9C, a resistance variable layer 124 and a passivation layer 126 are formed to cover the stacked structures 118, the conductive spacers 120a, the cover layer 109, and the third area 108c surrounded by the cup-shaped electrode 108 to complete the manufacture of a two-dimensional (2D) resistive memory device 100a. A material of the resistance variable layer 124 includes SiOx, HfOx, NiOx, TiOx, TiOxNy, TaOx, or WOx, where x, y can be some specific number in chemical stoichiometry. In an exemplary embodiment, as shown in FIG. 9B, the resistance variable layer 124 is filled into the undercut 122 (FIG. 8B) to connect with the sacrificial layer 113. A method of forming the resistance variable layer 124 filled into the undercut 122 includes an ALD or a CVD. In another exemplary embodiment, as illustrated in FIG. 9B-1, the undercut 122 (FIG. 8B) is not filled with the resistance variable layer 124 completely and a plurality of air gaps 128 is present between the resistance variable layer 124 and the sacrificial layer 113. A method of the resistance variable layer 124 for not filling the undercut 122 completely includes an ALD, a CVD, or a PVD. The passivation layer 126 can be constituted by a single material layer or two or more layers of material layers. A material of the passivation layer 126 includes SiNx, SiOx, or SiOxNy, where x, y can be any possible number in chemical stoichiometry. A method of forming the passivation layer 126 is, for example, a CVD method.

Referring to FIGS. 8A, 9B, and 9C, the resistive memory device 100a includes the bottom electrodes 104, the cup-shaped electrodes 108, the cover layer 109, the stacked structures 118, the sacrificial layer 113, the conductive spacers 120a, and the resistance variable layer 124. The bottom electrode 104 and the cup-shaped electrodes 108 are located in the insulating layers 102 and 112. Each of the cup-shaped electrodes has a bottom portion connected to the bottom electrode 104. The cover layer 109 is located above the insulating layer 112 and extends along the first direction. The cover layer 109 covers the first area 108a surrounded by the cup-shaped electrode 108 and exposes the second area 108b and the third area 108c surrounded by the cup-shaped electrode 108. Each of the stacked structures 118 includes the dielectric layer 114 and the top electrode 116. Each stacked structure 118 extends along the second direction to cover a portion of the cover layer 109 and the second area 108b surrounded by the cup-shaped electrode 108 and expose another portion of the cover layer 109 and the third area 108c surrounded by the cup-shaped electrode 108. The sacrificial layer 113 is located below the stacked structures 118 and covers the corresponding portion of the cover layer 109 and the second area 108b surrounded by the cup-shaped electrode 108. The conductive spacer 120a is located at a sidewall of each of the stacked structures 118. The resistance variable layer 124 covers the stacked structures 118, the conductive spacers 120a, the cover layer 109, and the third area 108c surrounded by the cup-shaped electrode 108.

A resistive memory device 100a′ shown in FIG. 9B-1 is similar to the resistive memory device 100a shown in FIG. 9B. The difference between the two is that the resistance variable layer 124 and the sacrificial layer 113 have the air gaps 128 therebetween. A portion of the resistance variable layer 124 and the passivation layer 126 are formed after the top electrode 116 is formed. Accordingly, current leakage caused by the damage of the resistance variable layer 124 from charge accumulation during the plasma etching process can be avoided completely.

The cup-shaped electrodes 108 in the resistive memory device 100a or 100a′ are square-shaped cups. The cover layer 109 formed above the cup-shaped electrodes 108 is used to cover half (this value is guided by the rule that only one side of two parallel conductive spacers of cup-shaped electrode within a cup along the direction of cover layer, the first direction, is exposed) of each of the cup-shaped electrodes 108, such that the conductive spacer 120a and the cup-shaped electrode 108 only intersect at a point to allow a one bit operation. Further, the resistive memory device 100a can form an array structure. The cup-shaped electrodes 108 each corresponds to a switch transistor (MOSFET), a diode, or an ovonic threshold switch (OTS) device (not shown).

Those with common knowledge in the art should understand that the structure of the resistive memory device is not limited to the structure aforementioned and alterations and variations can be made thereto. In the exemplary embodiment mentioned above, a plurality of cup walls of the cup-shaped electrodes substantially has the same height. However, the shape of the cup-shaped electrodes is not limited to the exemplary embodiment aforementioned. The cup walls of the cup-shaped electrodes can be of different heights.

FIGS. 10A to 18A are schematic top views illustrating methods of manufacturing a resistive memory device according to a third and a fourth exemplary embodiment. FIGS. 10B to 18B are schematic cross-sectional views taken along line V-V in the third exemplary embodiment shown in FIGS. 10A to 18A. FIG. 18B-1 is a schematic cross-sectional view taken along line V-V in the fourth exemplary embodiment shown in FIG. 18A. FIGS. 10C to 18C are schematic cross-sectional views taken along line VI-VI in the third and the fourth exemplary embodiments shown in FIGS. 10A to 18A.

Referring to FIGS. 10A, 10B, and 10C, a plurality of bottom electrodes 104 is formed in the insulating layer 102 according to the method illustrated in the above exemplary embodiment. Next, the insulating layer 106 having a plurality of openings 105 is formed on the insulating layer 102. Each of the openings 105 exposes the corresponding bottom electrode 104. A material of the insulating layer 106 includes SiOx, SiNx, or SiOxNy, where x, y can be any possible number in chemical stoichiometry. Subsequently, a cup-shaped electrode material layer 208 is formed on the insulating layer 102 to cover the insulating layer 106, a plurality of sidewalls of the openings 105, and the bottom electrodes 104. The openings 105 are then filled with a cover layer 210 to cover the cup-shaped electrode material layer 208 above the insulating layer 106. A material layer and the thickness of the cup-shaped electrode material layer 208 are as described above. Afterwards, a patterned mask layer 212 is formed above the cover layer 210. The patterned mask layer 212 extends along the first direction to cover a portion of the cover layer 210 above an area surrounded by the openings 105 so as to expose another portion of the cover layer 210 above the area surrounded by the openings 105. A material of the patterned mask layer 212 is photoresist, for example. A method of forming the patterned mask layer 212 is a photolithography process, for instance. In an exemplary embodiment, an area of the cover layer 210 above the area surrounded by the openings 105 and covered by the patterned mask layer 212 is ½ of the area surrounded by the openings 105. An area of the cover layer 210 above the area surrounded by the openings 105 and exposed by the patterned mask layer 212 is ½ of the area surrounded by the openings 105. However, the disclosure is not limited thereto.

Referring to FIGS. 11A, 11B, and 11C, a portion of the insulating layer 210 not covered by the patterned mask layer 212 is removed with a dry etching method, for example. In details, the cup-shaped electrode material layer 208 is adopted as an etch stop layer during the dry etching because the insulating layer 210 and the cup-shaped electrode material layer 208 have a higher etching selectivity therebetween (an etching selectivity of the insulating layer 210 to the cup-shaped electrode material layer 208 is larger than 4:1, for example). The insulating layer 210 not covered by the patterned mask layer 212 and outside of the area surrounded by the openings 105 is removed completely by an etching process until a surface of the cup-shaped electrode material layer 208 is exposed. Moreover, a portion of the insulating layer 210 not covered by the patterned mask layer 212 and above the area surrounded by the openings 105 is removed to keep a portion of the insulating layer 210 inside the openings 105 and expose the cup-shaped electrode material layer 208 on the sidewalls of the openings 105. In an exemplary embodiment, the thickness of the insulating layer 210 remained in the openings 105 is about ¼ of a depth of the openings 105, for example. However, the disclosure is not limited thereto. It is within the scope of the disclosure as long as the thickness of the insulating layer 210 remained in the openings 105 is thick enough to cover the cup-shaped electrode material layer 208 at bottom portions of the openings 105.

Referring to FIGS. 12A, 12B, and 12C, the insulating layer 106 is adopted as an etch stop layer because the cup-shaped electrode material layer 208 and the insulating layer 208 have a higher etching selectivity therebetween (an etching selectivity of the cup-shaped electrode material layer 208 to the insulating layer 106 is larger than 4:1, for example). The cup-shaped electrode material layer 208 above the insulating layer 106 and not covered by the patterned mask layer 212 as shown in FIGS. 11A, 11B, and 11C is removed to expose a surface of the insulating layer 106. In addition, the cup-shaped electrode material layer 208 exposed on the sidewalls of the openings 105 is removed to expose the sidewalls of the openings 105. A method of removing the cup-shaped electrode material layer 208 not covered by the patterned mask layer 212 is, for instance, a wet etching or isotropic dry etching methods. The cup-shaped electrode material layer 208 covered by the patterned mask layer 212 and the insulating layer 210 at the bottom portions of the openings 105 are remained.

Thereafter, referring to FIGS. 13A, 13B, and 13C, the patterned mask layer 212 is removed. A method of removing the patterned mask layer 212 is an oxygen plasma stripping method, for instance. Afterwards, an insulating layer 214 is formed to cover the insulating layer 210 and fill into a remaining space in the openings 105. The material of the insulating layer 214 is the same as or different from that of the insulating layer 210 or the insulating layer 106. A material of the insulating layer 214 includes SiOx, SiNx, or SiOxNy, where x, y can be any possible number in chemical stoichiometry. A method of forming the insulating layer 214 is a CVD, for example.

Referring to FIGS. 14A, 14B, and 14C, the insulating layers 214 and 210 in FIGS. 13A, 13B, and 13C are planarized to remove the insulating layers 214 and 210 outside of the openings 105 and remain the insulating layers 210 and 214 inside the openings 105 in the insulating layer 106. A method of planarizing the insulating layers 214 and 210 includes the following. For instance, the cup-shaped electrode material layer 208 is used as a polishing stop layer to remove a portion of the insulating layers 214 and 210 with a chemical mechanical polishing process. Later, the cup-shaped electrode material layer 208 above the insulating layer 216 is removed to form a cup-shaped electrode 208′ in each of the openings 105. In an exemplary embodiment, a cup bottom of the cup-shaped electrode 208′ is located at the bottom portion of the opening 105 and a cup wall of the cup-shaped electrode 208′ is located on the sidewall of the opening 105. The cup walls of the cup-shaped electrodes 208′ have at least two different heights. A portion of the cup walls have a height that is about the height of the openings 105. Another portion of the cup walls have a height that is lower than the height of the openings 105, which is about ⅓ of the height of the openings 105; however, the disclosure is not limited thereto. An area surrounded by each of the cup-shaped electrodes 208′ has a first area 208a, a second area 208b, and a third area 208c. In an exemplary embodiment, areas of the first area 208a, the second area 208b, and the third area 208c are respectively ½, ¼, and ¼ of an area surrounded by the cup-shaped electrode 208′, for example. Nevertheless, the disclosure is not limited thereto.

Afterwards, referring to FIGS. 15A, 15B, and 15C, the sacrificial layer 113, the dielectric layer 114, the top electrode layer 116, and the photoresist layer 115 are formed on the insulating layer 112. The photoresist layer 115 extends along the second direction to cover above the second area 208b surrounded by the cup-shaped electrode 208′, above a portion of the first area 208a, and the top electrode layer 116 above the insulating layer 106 in the surrounding. The second direction is substantially perpendicular to the first direction.

Next, referring to FIGS. 16A, 16B, and 16C, the top electrode layer 116 and the dielectric layer 114 are patterned according to the method illustrated in the exemplary embodiment abovementioned to form the stacked structures 118. Next, the photoresist layer 115 is removed. The stacked structures 118 extend along the second direction. The stacked structures 118 cover above the second area 208b surrounded by the cup-shaped electrode 208′, a portion of the first area 208a, and the insulating layer 106 at the periphery of the second area 208b and the portion of the first area 208a. The conductive spacers 120a are then formed on the sidewalls of the stacked structures 118 according to the method illustrated in the exemplary embodiments aforementioned.

Referring to FIGS. 17A, 17B, and 17C, the conductive spacers 120a and the stacked structures 118 are used as a mask to remove a portion of the sacrificial layer 113 to expose the cup-shaped electrode 208′ and the cover layer 210 on the third area 208c and the cover layer 214 above the first area 208a and the insulating layer 106 at the periphery of the third area 208c and first area 208a. Moreover, the undercut 122 (or referred as the recess) is formed below the conductive spacers 120a and the stacked structures 118.

Next, referring to FIGS. 18A, 18B, and 18C, the resistance variable layer 124 and the passivation layer 126 are formed to cover the stacked structures 118, the conductive spacers 120a, and the third area 208c surrounded by the cup-shaped electrode 208. In an exemplary embodiment, as shown in FIG. 18B, the resistance variable layer 124 is filled into the undercut 122 to connect with the sacrificial layer 113. In another exemplary embodiment, as illustrated in FIG. 51-1, the undercut 122 is not filled with the resistance variable layer 124 completely and the air gaps are present between the resistance variable layer 124 and the sacrificial layer 113.

Referring to FIGS. 18B and 18C, a resistive memory device 100b in the exemplary embodiment includes the bottom electrodes 104, the cup-shaped electrodes 208′, the cover layers 210 and 214, the stacked structures 118, the sacrificial layer 113, the conductive spacers 120a, and the resistance variable layer 124. A structure of the resistive memory device 100b is similar to that of the resistive memory device 100a; however, the two are different in the shapes of the cup-shaped electrodes 208′. Referring to FIG. 14C, the cup walls of the cup-shaped electrodes 208′ in the exemplary embodiment have at least two different heights. A portion of the cup walls have a height that is about the height of the openings 105. Another portion of the cup walls have a height that is lower than the height of the openings 105, which is about ⅓ of the height of the openings 105; however, the disclosure is not limited thereto. The cup walls having a lower height in the cup-shaped electrodes 208′ each has a top that is covered by the cover layer 214, while a cup bottom of each of the cup-shaped electrodes 208′ is covered by the cover layer 210. The cover layers 210, 214 and a plurality of upper surfaces of the cup walls having a higher height in the cup-shaped electrodes 208′ constitute a relatively flat surface.

In FIG. 14A, the cover layer 214 covers the first area 208a surrounded by the cup-shaped electrode 208′. The second area 208b and the third area 208c expose the cover layer 210 and the cup-shaped electrodes 208′. Additionally, the cup-shaped electrodes 208′ exposed by the second area 208b and the third area 208c have a U shape when observed from the top. Areas of the first area 208a, the second area 208b, and the third area 208c are respectively ½, ¼, and ¼ of an area surrounded by the cup-shaped electrode 208′, for example. Nevertheless, the disclosure is not limited thereto. The area covered by the cover layer 214 is not limited to ½ of the area surrounded by the cup-shaped electrode 208′ and can be smaller or larger than ½. It is within the scope of the disclosure as long as a region of the cup-shaped electrode 208′, which has the height of the cup walls is the same as the height of the openings 105 and the conductive spacer 120a only intersect at a point. In other words, a boundary A of the cover layer 214 can be between inner circumferences B and C of the cup-shaped electrode 208′. When the boundary A of the cover layer 214 is located on the inner circumference B of the cup-shaped electrode 208′ or between the inner circumferences B and C, the cup-shaped electrode 208′ exposed has a U shape when observed from the top. When the boundary A of the cover layer 214 is located on the inner circumference C of the cup-shaped electrode 208′, the cup-shaped electrode 208′ exposed has a strip shape when observed from the top.

Referring to FIGS. 18B-1 and 18C, a resistive memory device 100b′ in the exemplary embodiment includes the bottom electrodes 104, the cup-shaped electrodes 208′, the cover layers 210 and 214, the stacked structures 118, the sacrificial layer 113, the conductive spacers 120a, and the resistance variable layer 124. The resistive memory device 100b′ is similar to the resistive memory device 100b shown in FIG. 18B. The difference between the two is that the resistance variable layer 124 and the sacrificial layer 113 have the air gaps 128 therebetween.

The cup-shaped electrodes 208′ with the cup walls having the height lower than the height of the openings 105 are covered by the cover layer 214 in the resistive memory device 100b or 100b′. The cup-shaped electrodes 208′, which has the cup walls having the height is the same as the height of the openings 105 and in a U shape or a strip shape (observed from the top), only intersects with the conductive spacer 120a at one point. Thus, a one bit operation can be performed to the resistive memory device 100b. Since the conductive spacers 120a are formed on a planar surface, a width of the entire conductive spacer should be the same or substantially the same.

The exemplary embodiments are illustrated with a 2D resistive memory device. However, the resistive memory device in the disclosure can also be used to manufacture a three-dimensional (3D) array structure.

FIGS. 19A to 19B are schematic cross-sectional views illustrating a method of manufacturing a resistive memory device having a 3D array structure according to a fifth exemplary embodiment.

Referring to FIG. 19A, a bottom electrode 12 is formed on a substrate 10. The substrate 10 is a silicon substrate. In other embodiments, SiGe, bulk semiconductor, strained semiconductor, compound semiconductor, silicon on insulator (SPI), or other common semiconductor substrates can also be applied.

A material of the bottom electrode 12 is the same as that described for the bottom electrodes 104 in the first exemplary embodiment and the details are thus no reiterated hereinafter.

A plurality of diodes 14 is formed on the bottom electrode 12. The diodes 14 are utilized as a current switch. A method of forming the diodes 14 includes the following. A P-type semiconductor layer and an N-type semiconductor layer are first formed and then patterned with a photolithography process and an etching process to form a PN diode junction. A material of the semiconductor layer is silicon, for instance. A P-type dopant in the P-type semiconductor layer is boron or boron difluoride (BF₂). An N-type dopant in the N-type semiconductor layer is phosphorous or arsenite, for example. A method of forming the semiconductor layer is, for example, a CVD method. A material used to form the diodes is not limited to silicon.

Afterwards, an insulating layer 16 is formed on the bottom electrode 12 and the diodes 14. A material of the insulating layer 16 includes SiOx, SiNx, or SiOxNy, where x, y can be any possible number in chemical stoichiometry. A method of forming the insulating layer 16 is a CVD, for example. Subsequently, a plurality of cup-shaped electrodes 18 is formed in the insulating layer 16. The cup-shaped electrodes 18 can be formed using the method for forming the cup-shaped electrodes 108 or 208′ disclosed in the first exemplary embodiment or the third exemplary embodiment. In the figures, a drawing of the cup-shaped electrodes 108 in the first exemplary embodiment is used for illustration. The cover layer 109 and the sacrificial layer 113 are formed according to the manufacturing method in the exemplary embodiments aforementioned. The stacked structures 118 constituted by the dielectric layer 114 and the top electrode layer 116, the conductive spacers 120a located on the sidewalls of the stacked structures 118, the resistance variable layer 124, and the passivation layer 126 are formed to complete the manufacture of a first resistive memory device 10a.

An insulating layer 130 is then deposited blanketly to cover the passivation layer 126. A material of the insulating layer 130 includes SiOx, SiNx, or SiOxNy, where x, y can be any possible number in chemical stoichiometry. A method of forming the insulating layer 130 is a CVD, for example.

Referring to FIG. 19B, a planarization process is performed to remove a portion of the insulating layer 130, the passivation layer 126, and the resistance variable layer 124 so as to expose a surface of the top electrode layer 116. Afterwards, steps for forming the diodes 14 resistive memory device, the insulating layer 16, the cup-shaped electrodes 18, the cover layer 109, the sacrificial layer 113, the stacked structures 118, the conductive spacers 120a (not shown since the cross sections are dissected at different locations), the resistance variable layer 124, and the passivation layer 126 of the first resistive memory device 10a in FIG. 19A are repeated to form a second resistive memory device 10b. The sacrificial layer 113 of the second resistive memory device 10b is not shown since the cross sections are dissected at different locations. An extending direction of the sacrificial layer 113 is perpendicular to an extending direction of the conductive spacers 120a in the first resistive memory device 10a.

The diodes 14 in the second resistive memory device 10b are electrically connected to the top electrode layer 116 of the first resistive memory device 10a. The top electrode layer 116 of the first resistive memory device 10a is adopted as the bottom electrode layer 12 of the second resistive memory device 10b at the same time. The first resistive memory device 10a and the second resistive memory device 10b constitute a resistive memory device 10c having a 3D array structure.

Referring to FIG. 19B, the resistive memory device 10c having the 3D array structure in the third exemplary embodiment in the disclosure includes a substrate 10, the first resistive memory device 10a, and the second resistive memory device 10b. Nonetheless, the 3D resistive memory device 10c is not limited to a two-layer stacked structure constituted merely by the first resistive memory device 10a and the second resistive memory device 10b. The 3D resistive memory device 10c can include a multi-layer stacked structure constituted by a plurality of the first resistive memory devices 10a and a plurality of the second resistive memory devices 10b.

The first resistive memory device 10a is located between the substrate 10 and the second resistive memory device 10b. The second resistive memory device 10b and the first resistive memory device 10a are electrically connected. The first resistive memory device 10a and the second resistive memory device 10b each includes the bottom electrode 12, the diodes 14, the cup-shaped electrodes 18, the cover layer 109, the stacked structures 118, the sacrificial layer 113, the conductive spacers 120a, and the resistance variable layer 124.

Referring to FIG. 19B, the diodes 14, the bottom electrodes 104, and the cup-shaped electrodes 108 are located in the insulating layer 16. The diodes 14 are electrically connected to the cup-shaped electrodes 18 and the bottom electrodes 104. The cover layer 109 is located on the insulating layer 16. The cover layer 109 covers a portion of an area surrounded by the cup-shaped electrode 18 (similar to the first area 108a in FIG. 8A) to expose a portion of an area surrounded by the cup-shaped electrode 18 (similar to the second area 108b and the third area 108c in FIG. 8A). Each of the stacked structures 118 includes the dielectric layer 114 and the top electrode 116 and extends along the second direction to cover a portion of the cover layer 109 and a portion of an area surrounded by the cup-shaped electrode 18 (similar to the second area 108b in FIG. 8A) to expose another portion of the cover layer 109 and a portion of an area surrounded by the cup-shaped electrode 18 (similar to the third area 108c in FIG. 8A). The sacrificial layer 113 is located below the stacked structures 118 and covers the corresponding portion of the cover layer 109 and a portion of an area surrounded by the cup-shaped electrode 18 (similar to the second area 108b in FIG. 8A). The conductive spacers 120a are located at the sidewalls of the stacked structures 118. The resistance variable layer 124 covers the stacked structures 118, the conductive spacers 120a, the cover layer 109, and a portion of an area of the cup-shaped electrode 18 (similar to the third area 108c in FIG. 8A).

The extending directions of the cover layer 109, the sacrificial layer 113, the stacked structures 118, and the conductive spacers 120a in the second resistive memory device 10b are perpendicular to the cover layer 109, the sacrificial layer 113, the stacked structures 118, and the conductive spacers 120a in the first resistive memory device 10a respectively. A positional relationship of the cover layer 109, the sacrificial layer 113, the stacked structures 118, and the conductive spacers 120a is as illustrated above and not reiterated hereinafter.

FIG. 19B-1 is a schematic cross-sectional view illustrating another resistive memory device having a 3D array structure according to the fifth exemplary embodiment.

A resistive memory device 10c′ having the 3D array structure in FIG. 19B-1 is similar to the resistive memory array 10c having the 3D array structure in FIG. 7B. The greatest difference between the two is that the air gaps 128 are present between the resistance variable layer 124 and the sacrificial layer 113 in the first resistive memory device 10a and the second resistive memory device 10b.

FIG. 20A is a schematic cross-sectional view illustrating a resistive memory device having a 3D array structure according to a sixth exemplary embodiment.

Referring to FIG. 20A, a manufacturing method of a resistive memory device 10d′ having the 3D array structure in the exemplary embodiment is similar to the manufacturing method of the resistive memory device having the 3D array structure in the fifth exemplary embodiment. In both embodiments, the insulating layer 130 is deposited blanketly after the first resistive memory device 10a is manufactured and the same planarization process is performed. The greatest difference between the exemplary embodiment and the fifth exemplary embodiment is that in the manufacturing method of the resistive memory device 10d′ having the 3D array structure in the exemplary embodiment, the planarization process performed after the formation of the insulating layer 130 does not expose the surface of the top electrode layer 116. Another difference is that the bottom electrode 12 of the second resistive memory device 10b is additionally formed on the insulating layer 130 instead of adopting the top electrode layer 116 of the first resistive memory device 10a as the bottom electrode 12 of the second resistive memory device 10b. Further, another difference is that in the exemplary embodiment, the extending directions of the bottom electrode 12, the cover layer 109, the sacrificial layer 113, the stacked structures 118, and the conductive spacers 120a in the second resistive memory device 10b are parallel, instead of perpendicular, to the bottom electrode 12, the cover layer 109, the sacrificial layer 113, the stacked structures 118, and the conductive spacers 120a in the first resistive memory device 10a respectively.

Similarly, in the exemplary embodiment, the first resistive memory device 10a and the second resistive memory device 10b constitute a resistive memory device 10d having a 3D array structure. Nonetheless, the 3D resistive memory device 10d is not limited to a two-layer stacked structure constituted merely by the first resistive memory device 10a and the second resistive memory device 10b. The 3D resistive memory device 10d can include a multi-layer stacked structure constituted by a plurality of the first resistive memory devices 10a and a plurality of the second resistive memory devices 10b.

FIG. 20A-1 is a schematic cross-sectional view illustrating another resistive memory device having a 3D array structure according to the sixth exemplary embodiment.

A resistive memory device in FIG. 20A-1 is similar to the resistive memory array having the 3D array structure in FIG. 20A. The greatest difference between the two is that the air gaps 128 are present between the resistance variable layer 124 and the sacrificial layer 113 in the first resistive memory device 10a and the second resistive memory device 10b.

In summary, in the method of manufacturing the resistive memory device in the exemplary embodiments, the sacrificial layer is formed before the stacked structures are formed, such that the sacrificial layer can be adopted as the etch stop layer in the etching process for patterning the stacked structures and the conductive spacers. Therefore, the cup-shaped electrodes below the sacrificial layer are prevented from being damaged by longitudinal or lateral etching due to overetch.

In addition, after the stacked structures and the conductive spacers are formed, a portion of the sacrificial layer is removed to generate the undercut below the stacked structures and the conductive spacers. The resistance variable layer subsequently formed can backfill and fill the undercut completely, so that the resistance variable layer and the sacrificial layer contact each other directly. On the other hand, a portion of the undercut can be remained so that the resistance variable layer and the sacrificial layer do not contact each other directly, thereby forming the air gaps therebetween.

Moreover, the resistance variable layer is first formed and the top electrode is then formed in the conventional methods. The method of manufacturing the resistive memory device in the exemplary embodiments includes forming the top electrode first and then forming the resistance variable layer. Consequently, the methods in the exemplary embodiment can prevent the damages on the resistance variable layer caused by the conventional methods in the etching process for patterning the top electrode.

Furthermore, in the exemplary embodiments, the size of the conductive spacers is reduced beyond the limits of the photolithography machine through the film deposition process and etching process. As a result, the locations which the variable resistances are formed in the resistive memory device are limited, so that the set state and the reset state of the variable resistances are more stable and more convergent.

It is known that the larger the active regions, the more difficult it is to control the locations and distribution of resistive filaments, thereby leading to severe resistance drift. In the exemplary embodiments in the disclosure, the active regions of the resistive memory device are located at boundaries of the cup-shaped electrodes and the resistance variable layer. In other words, the resistance memory device in the exemplary embodiments has ultra-small active regions beyond the limits of the photolithography machine, where the resistance switching position of resistances can be controlled to overcome the resistance drift effectively and enhance the performance of the device.

Moreover, the top electrode layer of the resistive memory device structure in the bottom layer of the 3D phase resist memory device in the exemplary embodiments can share the bottom electrode layer of the resistive memory device structure in the top layer to save the cost of materials and related manufacture time. Additionally, the contact area between the conductive spacers and the cup-shaped electrodes can be controlled by the area intersected by the resistance variable layer and the cup-shaped electrode to minimize the contact area, limit the switching position of the resistances, overcome the resistance drift, and enhance the device performance.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A method of manufacturing a resistive memory device, the method comprising:
forming a bottom electrode and a cup-shaped electrode in an insulating layer, the cup-shaped electrode having a bottom portion connected to the bottom electrode;
forming a cover layer covering a first area surrounded by the cup-shaped electrode and exposing a second area and a third area surrounded by the cup-shaped electrode;
forming a sacrificial layer, a dielectric layer, and a top electrode layer;
patterning the dielectric layer and the top electrode layer using the sacrificial layer as an etch stop layer to form a stacked structure, the stacked structure covering a top of the second area, a top of a portion of the first area surrounded by the cup-shaped electrode, and the sacrificial layer above the insulating layer;
forming a conductive spacer material layer on the sacrificial layer and the stacked structure;
etching the conductive spacer material layer using the sacrificial layer as the etch stop layer to form a conductive spacer at a sidewall of the stacked structure; and
removing a portion of the sacrificial layer using the conductive spacer and the stacked structure as a mask to form an undercut below the conductive spacer and the stacked structure to expose a surface of a portion of the cover layer, the third area surrounded by the cup-shaped electrode, and the insulating layer at the periphery of the portion of the cover layer and the third area.

2. The method of manufacturing the resistive memory device as claimed in claim 1, wherein a method of removing a portion of the sacrificial layer comprises:
performing an anisotropic etching process to remove the sacrificial layer not covered by the conductive spacer and the stacked structure; and
performing an isotropic etching process to remove a portion of the sacrificial layer below the conductive spacer and the stacked structure.

3. The method of manufacturing the resistive memory device as claimed in claim 1, further comprising forming a resistance variable layer to cover the stacked structure, the conductive spacer, the cover layer, the third area, and the insulating layer, wherein the resistance variable layer is filled into the undercut to connect with the sacrificial layer.

4. The method of manufacturing the resistive memory device as claimed in claim 3, wherein the undercut is not filled with the resistance variable layer completely, such that the resistance variable layer and the sacrificial layer have an air gap therebetween.

5. The method of manufacturing the resistive memory device as claimed in claim 3, wherein a method of forming the resistance variable layer comprises an atomic layer deposition, a chemical vapor deposition, or a physical sputtering method.

6. The method of manufacturing the resistive memory device as claimed in claim 1, wherein a material of the sacrificial layer comprises a metal oxide.

7. The method of manufacturing the resistive memory device as claimed in claim 6, wherein a material of the sacrificial layer comprises NiOx, CoOx, or basically a material having a selectivity larger than 30, etchable by plasma in CO/NH₃ environment, and almost not etchable by a plasma based on fluorine or chlorine environment.

8. The method of manufacturing the resistive memory device as claimed in claim 3, wherein a material of the resistance variable layer comprises a metal oxide.

9. The method of manufacturing the resistive memory device as claimed in claim 8, wherein a material of the resistance variable layer comprises SiOx, HfOx, NiOx, TiOx, TiOxNy, TaOx, or WOx.

10. The method of manufacturing the resistive memory device as claimed in claim 1, wherein a material of the cup-shaped electrode comprises a metal, a metal nitride, a metal silicide, or a stacked layer having a combination thereof.

11. The method of manufacturing the resistive memory device as claimed in claim 1, wherein a material of the conductive spacer comprises TaN, TiN, WN, TiW, Ti, Ta, W, Ni, Co, Zr, Ru, RuOx, Pt, Al, Cu, or a stacked layer of the same.

12. The method of manufacturing the resistive memory device as claimed in claim 1, wherein the cover layer is formed above the insulating layer.

13. The method of manufacturing the resistive memory device as claimed in claim 1, wherein the cover layer is formed in the insulating layer.

14. A resistive memory device, comprising:
a bottom electrode located in an insulating layer;
a cup-shaped electrode located in the insulating layer and above the bottom electrode, the cup-shaped electrode having a bottom portion connected to the bottom electrode;
a cover layer covering a first area surrounded by the cup-shaped electrode and exposing a second area and a third area surrounded by the cup-shaped electrode;
a stacked structure comprising a dielectric layer and a top electrode, extending along a second direction, covering a portion of the cover layer on the first area and the second area surrounded by the cup-shaped electrode, and exposing another portion of the cover layer on the first area and the third area;
a sacrificial layer located below the stacked structure and covering a portion of the cover layer on the first area and the second area surrounded by the cup-shaped electrode; and
a conductive spacer located at a sidewall of the stacked structure.

15. The resistive memory device as claimed in claim 14, further comprising a resistance variable layer covering the stacked structure, the conductive spacer, the cover layer, and the third area of the cup-shaped electrode, wherein the conductive spacer and the stacked structure have an undercut below and the resistance variable layer is filled into the undercut.

16. The resistive memory device as claimed in claim 15, wherein the resistance variable layer in the undercut is connected to the sacrificial layer.

17. The resistive memory device as claimed in claim 15, wherein the undercut is not filled with the resistance variable layer completely, such that the resistance variable layer, the sacrificial layer, the conductive spacer, and the stacked structure have an air gap therebetween.

18. The resistive memory device as claimed in claim 14, wherein a material of the sacrificial layer comprises a metal oxide.

19. The resistive memory device as claimed in claim 18, wherein a material of the sacrificial layer comprises NiOx, CoOx, or basically a material having a selectivity larger than 30, etchable by plasma in CO/NH₃ environment, and almost not etchable by a plasma based on fluorine or chlorine environment.

20. The resistive memory device as claimed in claim 15, wherein a material of the resistance variable layer comprises a metal oxide.

21. The resistive memory device as claimed in claim 20, wherein a material of the resistance variable layer comprises SiOx, HfOx, NiOx, TiOx, TiOxNy, TaOx, or WOx.

22. The resistive memory device as claimed in claim 14, wherein a material of the cup-shaped electrode comprises a metal, a metal nitride, or a metal silicide.

23. The resistive memory device as claimed in claim 14, wherein a material of the conductive spacer comprises TaN, TiN, WN, TiW, Ti, Ta, W, Ni, Co, Zr, Ru, RuOx, Pt, Al, Cu, or a stacked layer of the same.

24. The resistive memory device as claimed in claim 14, wherein a plurality of cup walls of the cup-shaped electrode has a same height.

25. The resistive memory device as claimed in claim 24, wherein the cover layer is located above the insulating layer.

26. The resistive memory device as claimed in claim 25, wherein a plurality of cup walls of the cup-shaped electrode has at least two different heights.

27. The resistive memory device as claimed in claim 26, wherein the cover layer is located in the insulating layer.

28. A resistive memory device, comprising:
a substrate;
a first resistive memory device located on the substrate;
a second resistive memory device located on the first resistive memory device and electrically connected to the first resistive memory device, wherein the first resistive memory device and the second resistive memory device each comprises:
a bottom electrode;
a diode located in a first insulating layer above the bottom electrode;
a cup-shaped electrode located in the first insulating layer, the cup-shaped electrode contacting and electrically connected to the diode;
a cover layer covering a first area surrounded by the cup-shaped electrode and exposing a second area and a third area surrounded by the cup-shaped electrode;
a stacked structure comprising a dielectric layer and a top electrode, covering a portion of the cover layer on the first area and the second area of the cup-shaped electrode, and exposing another portion of the cover layer on the first area and the third area surrounded by the cup-shaped electrode;
a sacrificial layer located below the stacked structure and covering a corresponding portion of the cover layer and the second area surrounded by the cup-shaped electrode; and
a conductive spacer located at a sidewall of the stacked structure.

29. The resistive memory device as claimed in claim 28, wherein the top electrode in the first resistive memory device is adopted as the bottom electrode in the second resistive memory device.

30. The resistive memory device as claimed in claim 29, wherein an extending direction of the sacrificial layer in the first resistive memory device is substantially perpendicular to an extending direction of the sacrificial layer in the second resistive memory device.

31. The resistive memory device as claimed in claim 28, further comprising a second insulating layer sandwiched between the first resistive memory device and the second resistive memory device.

32. The resistive memory device as claimed in claim 31, wherein an extending direction of the sacrificial layer in the first resistive memory device is substantially parallel to an extending direction of the sacrificial layer in the second resistive memory device.

33. The resistive memory device as claimed in claim 28, wherein a plurality of cup walls of the cup-shaped electrode has a same height.

34. The resistive memory device as claimed in claim 33, wherein the cover layer is located above the insulating layer.

35. The resistive memory device as claimed in claim 28, wherein a plurality of cup walls of the cup-shaped electrode has at least two different heights.

36. The resistive memory device as claimed in claim 35, wherein the cover layer is located in the insulating layer.

37. The resistive memory device as claimed in claim 28, further comprising a resistance variable layer covering the stacked structure, the conductive spacer, the cover layer, and the third area surrounded by the cup-shaped electrode, wherein the conductive spacer and the stacked structure have an undercut below and the resistance variable layer is filled into the undercut.

38. The resistive memory device as claimed in claim 37, wherein the resistance variable layer in the undercut is connected to the sacrificial layer.

39. The resistive memory device as claimed in claim 37, wherein the undercut is not filled with the resistance variable layer completely, such that the resistance variable layer, the sacrificial layer, the conductive spacer, and the stacked structure have an air gap therebetween.
